(19) United States
(12) Patent Application Publication
(10) Pub. No.: US 2008/0217754 A1
(43) Pub. Date: Sep. 11, 2008

(54) SEMICONDUCTOR DEVICE AND MANUFACTURING METHOD THEREOF

(75) Inventors: Akira TOJO, Yokohama-shi (JP); Tomoyuki Kitani, Yokohama-shi (JP); Tomohiro Iguchi, Kawasaki-shi (JP); Masako Hirahara, Yokohama-shi (JP); Hideo Nishiuchi, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/044,299

(22) Filed: Mar. 7, 2008

(30) Foreign Application Priority Data
Mar. 8, 2007 (JP) 2007-058564
Sep. 21, 2007 (JP) 2007-245852

(51) Int. Cl. H01L 23/48; H01L 21/00

(52) U.S. Cl. 257/690; 438/118; 257/E23.141

(57) ABSTRACT

A semiconductor device includes a semiconductor chip 5 having a first surface 5a on which a first pole 5a1 of a semiconductor element is arranged and a second surface 5b on which a second pole 5b1 is arranged and which is opposed to the first surface 5a, a first conductive member 6a connected to the first surface 5a, a second conductive member 6b connected to the second surface 5b, a first external electrode 2a connected to the first conductive member 6a and having a contact area larger than the member 6a, a second external electrode 2b connected to the second conductive member 6b and having a contact area larger than the conductive member 6b and a sealing member 3 sealing up the semiconductor chip 6 and the conductive members 6 between the first external electrode 2a and the second external electrode 2b. The sealing member 3 is provided as a result of heating a sealing material for melting and subsequent hardening. A manufacturing method of the semiconductor device is also provided to improve its electrical characteristics and productivity.

### BACKGROUND OF THE INVENTION

1. Field of the Invention

The present invention relates to a semiconductor device having a built-in semiconductor chip and a manufacturing method of such a semiconductor device.

2. Description of Related Art

In prior art, an electrical connection between a semiconductor chip and an external electrode has been effected by means of wire-bonding, as described in Japanese Patent Publication Laid-open No. 2006-278520. Referring to FIG. 1, we now explain a semiconductor device using wire-bonding, in brief. First, the shown semiconductor device 1000 includes a semiconductor chip 1001 having a front pole 1001a and a back pole 1001b. The semiconductor device 1000 further includes two external electrodes 1002, 1003 mounted on wiring pads 1007 formed on a substrate 1006. The external electrodes 1002, 1003 are electrically connected to the wiring pads 1007 through not-shown conductive members. As for the electrical connection between the above-mentioned external electrodes 1002, 1003 and the semiconductor chip 1001, the back electrode 1001b is connected to the external electrode 1002 through a not-shown conductive member as well, while the front electrode 1001a is connected to the other external electrode 1003 through a bonding wire 1004 accomplishing the above-mentioned wire-bonding. The so-formed semiconductor device 1000 is sealed up with a sealing resin 1005 in an airtight manner.

Another exemplary connecting form for the semiconductor device is shown in FIG. 2. In FIG. 2, a semiconductor device 1010 comprises a multilayer capacitor 1011 and a pair of external electrodes 1012, 1012 connected to both sides of the multilayer capacitor 1011 respectively. Each of the external electrodes 1012 is provided, except for its surface connected to the multilayer capacitor 1011, with five electrode surfaces. In arrangement, the semiconductor device 1010 is arranged so that the external electrodes 1012, 1012 lie on wiring pads 1014 formed on a substrate 1013. The electrical connection between the external electrodes 1012, 1012 and the wiring pads 1014 are accomplished by mounted solders 1015, 1015.

However, it should be noted that the former semiconductor device adopting the bonding wire raises a problem to be solved, as follows

With the progress of electronic equipments, such as mobile telephones, there is a requirement of improving the electrical characteristics of electronic components. In the above semiconductor device using the bonding wire, nevertheless, it is difficult to improve the electrical characteristics of the device since its electrical resistance value is increased at the bonding wire. Additionally, as the front pole 1001a of the semiconductor chip 1001 is connected to the external electrode 1003 one on one shown in FIG. 1, it is impossible to reduce the number of manufacturing processes and the manufacturing time, apart from the improvement of productivity.

Although the latter semiconductor device 1010 of FIG. 2 enables the electrical characteristics to be improved in comparison with the former semiconductor device 1000 due to no-use of bonding wire, there is an inherent problem that internal elements might be broken in manufacturing the multilayer capacitor 1011. In detail, the multilayer capacitor 1011 of FIG. 2 is manufactured by applying thermo-compression on a laminated structure where hard insulator layers in lamination are interposed between the internal elements. If mounting a semiconductor chip on the multilayer capacitor 1011, there arises a possibility that the semiconductor chip is damaged by load applied on the multilayer capacitor 1011 at the thermo-compression, deteriorating the process yield.

Further, an exfoliation may arise between the semiconductor chip and members interposing the chip by a reliability test or an impact of drop. This would be also at the root of deteriorating the process yield.

In common with the semiconductor devices of FIGS. 1 and 2, it is necessary to exhibit two polarities with respect to each device as a product. This is also at the root of damping the improvement in productivity.

### SUMMARY OF THE INVENTION

In the above-mentioned situation, it is an object of the present invention to provide a semiconductor device and its manufacturing method both capable of ensuring high reliability while improving its electrical characteristics with the structure requiring no bonding wires and also improving the productivity with raised process yield.

In order to attain the above object, according to a first aspect of the present invention, there is provided a semiconductor device comprising: a semiconductor chip having a first surface on which a first pole of a semiconductor element is arranged and a second surface on which a second pole of the semiconductor element is arranged, the first surface opposing the second surface; a first conductive member connected to the first surface of the semiconductor chip; a second conductive member connected to the second surface of the semiconductor chip; a first external electrode connected to the first conductive member, the first external electrode having a contact area larger than that of the first conductive member; a second external electrode connected to the second conductive member, the second external electrode having a contact area larger than that of the second conductive member; and a sealing member arranged between the first external electrode and the second external electrode to seal up the semiconductor chip, the first conductive member and the second conductive member, wherein the sealing member is made of a material that can be molten and subsequently hardened by heating.

According to a second aspect of the present invention, there is also provided a manufacturing method of a semiconductor device, comprising the steps of: forming a plurality of through-holes in a first sheet-shaped sealing material and a second sheet-shaped sealing material respectively; adhering the first and the second sheet-shaped members having the through-holes to a first external electrode and a second external electrode respectively; filling a conductive material in each of the through-holes formed in the first and the second sheet-shaped sealing materials to thereby form a first conductive member and a second conductive member; preparing a semiconductor chip having a first surface on which a first pole of a semiconductor element is arranged and a second surface on which a second pole of the semiconductor element is arranged, the first surface opposing the second surface; connecting the first conductive member and the second conductive member to the first pole of the semiconductor chip and the second pole of the semiconductor chip, respectively; applying pressure and heat on the first external electrode and the second external electrode toward the semiconductor chip interposed between the first conductive member and the second conductive member to melt the first sheet-shaped sealing material and the second sheet-shaped sealing material thereby sealing up the semiconductor chip, the first conductive member and the second conductive member; and further heating the first sheet-shaped sealing material and the second sheet-shaped sealing material to harden them.

### BRIEF DESCRIPTION OF THE DRAWINGS

FIG. 1 is a sectional view of a semiconductor device in prior art;

FIG. 2 is a sectional view of another semiconductor device in prior art;

FIG. 3 is a perspective view showing an overall semiconductor device in accordance with a first embodiment of the present invention;

FIG. 4 is a perspective view explaining the inside structure of the semiconductor device in the first embodiment of the present invention;

FIG. 5 is a sectional view taken along a line A-A of the semiconductor device of FIG. 4;

FIG. 6 is a view showing a first step of the manufacturing method of the semiconductor device in the first embodiment of the present invention;

FIG. 7 is a view showing a second step of the manufacturing method of the semiconductor device in the first embodiment;

FIG. 8 is a view showing a third step of the manufacturing method of the semiconductor device in the first embodiment;

FIG. 9 is a sectional view of an overall semiconductor device in accordance with a second embodiment of the present invention;

FIG. 10 is another sectional view of the semiconductor device in the second embodiment of the present invention;

FIG. 11 is a view showing a first step of the manufacturing method of the semiconductor device in the second embodiment of the present invention;

FIG. 12 is a view showing a second step of the manufacturing method of the semiconductor device in the second embodiment;

FIG. 13 is a view showing a third step of the manufacturing method of the semiconductor device in the second embodiment;

FIG. 14 is a perspective view showing an overall semiconductor device in accordance with a third embodiment of the present invention;

FIG. 15 is a sectional view taken along a line B-B of the semiconductor device of FIG. 14;

FIG. 16 is a view showing a first step of the manufacturing method of the semiconductor device in the third embodiment of the present invention;

FIG. 17 is a view showing a second step of the manufacturing method of the semiconductor device in the third embodiment;

FIG. 18 is a view showing a third step of the manufacturing method of the semiconductor device in the third embodiment;

FIG. 19 is a perspective view showing an overall semiconductor device in accordance with a fourth embodiment of the present invention;

FIG. 20 is a sectional view taken along a line C-C of the semiconductor device of FIG. 19;

FIG. 21 is a view showing a first step of the manufacturing method of the semiconductor device in the fourth embodiment of the present invention;

FIG. 22 is a view showing a second step of the manufacturing method of the semiconductor device in the fourth embodiment;

FIG. 23 is a view showing a third step of the manufacturing method of the semiconductor device in the fourth embodiment;

FIG. 24 is a view showing a fourth step of the manufacturing method of the semiconductor device in the fourth embodiment;

FIG. 25 is a perspective view showing an overall semiconductor device in accordance with a fifth embodiment of the present invention;

FIG. 26 is a sectional view taken along a line D-D of the semiconductor device of FIG. 25;

FIG. 27 is a view showing a first step of the manufacturing method of the semiconductor device in the fifth embodiment of the present invention;

FIG. 28 is a view showing a second step of the manufacturing method of the semiconductor device in the fifth embodiment;

FIG. 29 is a view showing a third step of the manufacturing method of the semiconductor device in the fifth embodiment;

FIG. 30 is a view showing a fourth step of the manufacturing method of the semiconductor device in the fifth embodiment;

FIG. 31 is a view showing a fifth step of the manufacturing method of the semiconductor device in the fifth embodiment;

FIG. 32 is a perspective view showing an overall semiconductor device in accordance with a sixth embodiment of the present invention;

FIG. 33 is a sectional view taken along a line E-E of the semiconductor device of FIG. 32;

FIG. 34 is a view showing a first step of the manufacturing method of the semiconductor device in the sixth embodiment of the present invention;

FIG. 35 is a view showing a second step of the manufacturing method of the semiconductor device in the sixth embodiment;

FIG. 36 is a perspective view showing an overall semiconductor device in accordance with a seventh embodiment of the present invention;

FIG. 37 is a sectional view taken along a line F-F of the semiconductor device of FIG. 36;

FIG. 38 is a view showing a first step of the manufacturing method of the semiconductor device in the seventh embodiment of the present invention; and

FIG. 39 is a view showing a second step of the manufacturing method of the semiconductor device in the seventh embodiment.

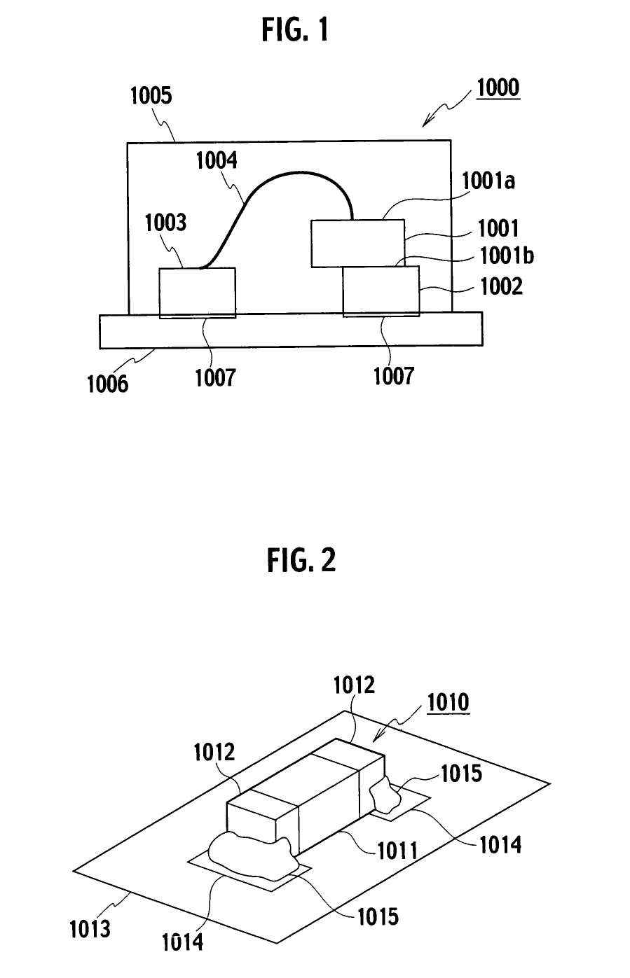

### DETAILED DESCRIPTION OF THE PREFERRED EMBODIMENTS

Embodiments of the present invention will be described with reference to attached drawings.

### 1^{st}. Embodiment

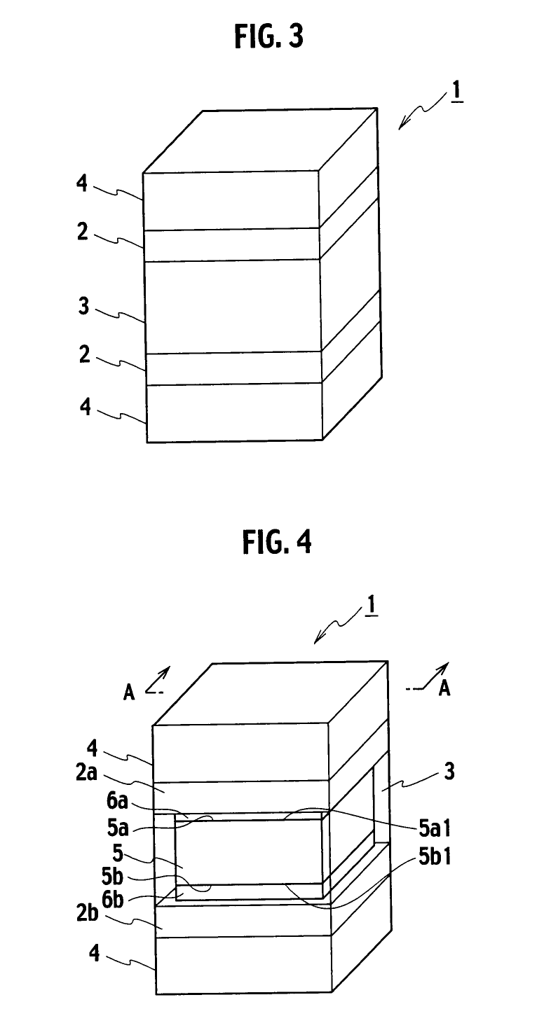

According to the first embodiment, a semiconductor device 1 as a whole is provided in the form of a substantially-rectangular parallelepiped shown in FIG. 3. The semiconductor device 1 has a pair of external electrodes 2, 2. The same device 1 is also provided, between the electrodes 2, 2, with an area sealed up with a sealing member 3. The sealing member 3 serves to seal up a semiconductor chip (not shown in FIG. 3) inside the semiconductor device 1. The external electrodes 2, 2 are subjected to plating. Thus, each of the external electrodes 2, 2 has plating films 4 formed on respective surfaces except for one surface in contact with the sealing member 3, providing a so-called “pentameric” electrode having five polar surfaces. The color of the sealing member 3 may be selected optionally. Therefore, by adopting the sealing members 3 in different colors in sealing up the semiconductor chips, it is also possible to produce the semiconductor devices 1 representing their polarity individually. It is noted that the semiconductor device 1 is used in the above-mentioned manner shown in FIG. 2.

FIG. 4 is an explanatory view representing a semiconductor chip 5 visible from the outside, assuming that the sealing member 3 is made of transparent material. Also, the semiconductor chip 5 is in the form of a substantially-rectangular parallelepiped. The semiconductor chip 5 is arranged so that its shortitudinal direction is paralleled with the longitudinal direction of the semiconductor device 1. The semiconductor chip 5 is provided, on its first surface 5a, with a first pole 5a1 of a semiconductor element. In the semiconductor element, its second pole 5b1 is arranged on a second surface 5b opposing the first surface 5a.

A first conductive member 6a is connected to the first surface 5a of the semiconductor chip 5, while a second conductive member 6b is connected to the second surface 5b. Outside the first conductive member 6a in the longitudinal direction of the device 1, a first external electrode 2a is connected to the other surface of the member 6a. Similarly, a second external electrode 3b is connected to the other surface of the second conductive member 6b.

With the above-mentioned arrangement of the semiconductor chip 5 inside the semiconductor device 1, as chip's opposing surfaces each having a maximum area in the semiconductor chip 5 can be allocated to its conductive surfaces for electrical contact with the external electrodes 2a, 2b (i.e. the conductive members 6a, 6b), it is possible to improve the electrical characteristics of the semiconductor device 1. In operation, current flows through the external electrode 2b, the second conductive member 6b, the second surface 5b (the second pole 5b1, the first surface 5a (the first pole 5a1), the first conductive member 6a and finally, through the external electrode 2a, in this order or flows though these elements in the opposite direction.

Each area of the first and the second surfaces 5a, 5b (or each sectional area of the first and the second conductive members 6a, 6b) is larger than each sectional area of the first and the second external electrodes 2a, 2b. With such dimensions of the semiconductor chip 5 and the conductive members 6a, 6b, it is possible to arrange these components at a substantially intermediate part of the semiconductor device 1, allowing the circumferences of the semiconductor chip 5 and the conductive members 6a, 6b to be covered with the sealing member 3 throughout.

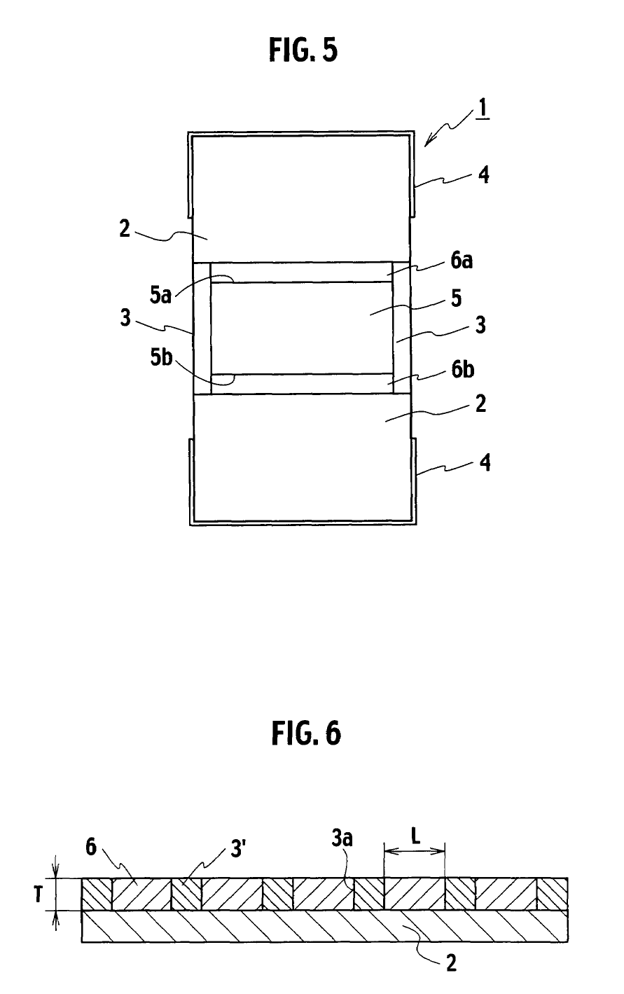

FIG. 5 is a sectional view of the semiconductor device 1, taken along a line A-A of FIG. 4. The semiconductor chip 5 is positioned at a substantial center of the semiconductor device 1 in the longitudinal direction and also interposed between the external electrodes 2 (2a, 2b) in pairs through the conductive members 6a, 6b. Further interposed between the external electrodes 2 is the above sealing member 3 in which the semiconductor chip 5 and the conductive members 6a, 6b are enclosed. As mentioned above, the plating films 4 are formed on five surfaces of each external electrode 2. In the illustrated embodiment, each of the conductive members 6a, 6b is formed to have its connection area equal to the whole area of an electrode surface of the semiconductor chip 5a in order to make the conductive member 6a (6b) contact with the whole electrode surface of the chip 5.

Referring to FIGS. 6 to 8, the manufacturing method of the semiconductor device 1 in the first embodiment will be described below.

First, a sealing material 3′ in the form of a sheet is prepared. This sheet-shaped sealing material 3′ has features of being molten by heating it up to a predetermined temperature (e.g. 130 degrees centigrade) for fluidization and nevertheless hardened since a further heating-up reaches e.g. 175 degrees centigrade. Thus, the sheet-shaped sealing material 3′ can be formed to have an optional profile by pressurizing it during the fluidization, which is superior to its machinability. Additionally, it is also possible to modify only the color of the sheet-shaped sealing material 3 without altering its material properties.

A thickness T (see FIG. 6) of the sheet-shaped sealing material 3′ may be one of various values corresponding to the thicknesses of the conductive members 6 to be connected to the semiconductor chip 5. The so-determined thickness of the material 3′ exerts an influence on dimensions of the semiconductor device 1.

Next, by an operation using laser or drill (both not shown), a plurality of through-holes 3a are formed in the sheet-shaped sealing material 3′ to receive the conductive members 6 (see FIG. 6). As for each the through-hole 3a, its bore diameter L may be optionally determined corresponding to the electrical characteristics of the semiconductor device 1. The larger the bore diameter L of the through-hole 3a gets, the greater the size of the conductive member 6 to be filled in the hole 3a does become with an increased connection area of the first or the second electrodes 5a1, 5b1 with the member 6. Thus, by determining the size of the conductive member 6, it is possible to control a conductive-path diameter of the semiconductor device 1, allowing an adjustment of its electrical characteristics. In connection, there is no possibility that the conductive member 6 has an area larger than the cross section of the semiconductor device 1, although the former is equal to the latter in FIGS. 6 to 8.

Using a not-shown laminating machine (called “laminator” generally), for example, the sheet-shaped sealing material 3′ having the through-holes 3a formed therein is press-fitted to the external electrode 2 temporarily. As the semiconductor device 1 requires a pair of external electrodes 2 having the press-fitted sheet-shaped sealing materials 3′, 3′, it is necessary to prepare two or more “in-process” products each having the sheet-shaped sealing material 3′ fitted to the external electrode 2.

Next, the through-holes 3a of the sheet-shaped sealing material 3′ temporarily press-fitted to the external electrode 2 are filled up with conductive members (conductive material) 6, as shown in FIG. 6. For the conductive members 6, for example, paste of silver (Ag) or copper (Cu) is available. The conductive material is charged into the through-holes 3a by an appropriate method, such as printing.

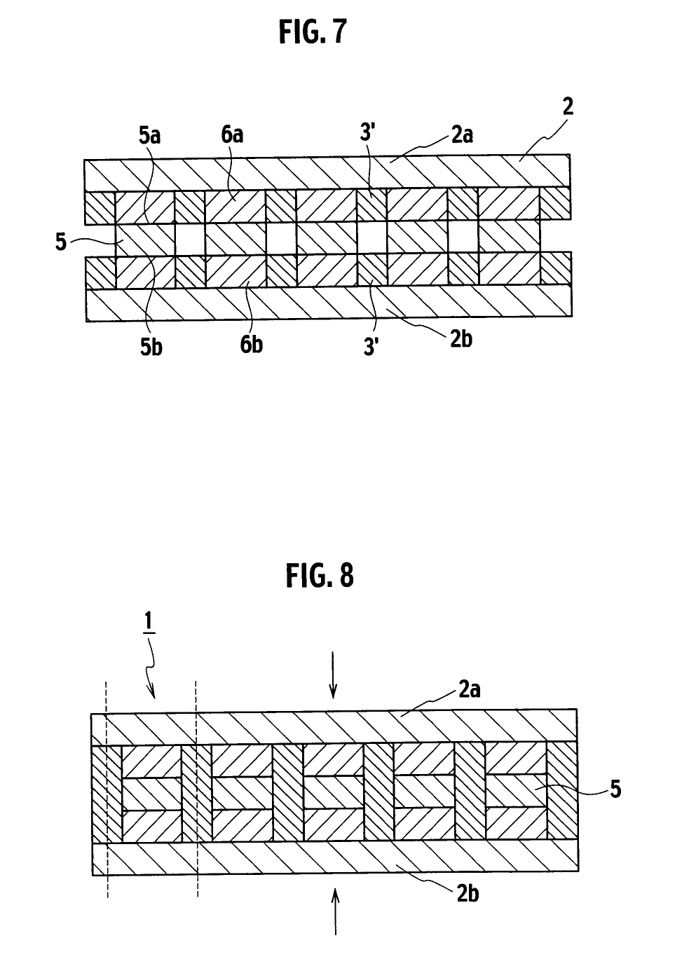

Next, the semiconductor chips 5 are mounted on the second external electrode 2b so that the second surface 5b of each chip 5 abuts on the second conductive member 6b on the electrode 2b. On the other hand, the first electrode 2a having the sheet-shaped sealing material 3′ press-fitted thereto is mounted on the semiconductor chips 5 so that the first conductive member 6a abuts on the first surface 5a of each chip 5. In this way, the semiconductor chips 5 are sandwiched between the first external electrode 2a and the second electrode 2b, as shown in FIG. 7.

Then, as shown with arrows of FIG. 8, pressure with heat is applied on the first external electrode 2a and the second electrode 2b interposing the semiconductor chips 5. Consequently, the sheet-shaped sealing materials 3′, 3′ are molten at e.g. 130 degrees centigrade to fill respective spaces each between the adjoining semiconductor chips 5. When it is performed to continue the heating operation and subsequently, this “in-process” product is left as it is for an hour or so at approx. 175 degrees centigrade, the sealing materials 3′, 3′ are hardened to be the sealing member 3 as a constituent of the semiconductor device 1. In this way, the semiconductor chips 5 are sealed up with the sealing members 3, together with the conductive members 6. In connection, when the sheet-shaped sealing materials 3′ are hardened on both sides of the semiconductor chips 5, the conductive members 6 making contact with the poles of the semiconductor chips 5 are also hardened simultaneously.

After the sheet-shaped sealing materials 3′ and the conductive members 6 (6a, 6b) are together hardened, the resultant integrated body (in-process product) is diced, between the adjoining semiconductor chips 5, by a dicing cutter thinner than an interval of the adjoining semiconductor chips 5, as shown with broken lines of FIG. 8. In this way, the individual semiconductor device 1 of FIG. 3 is completed. Subsequently, the first external electrode 2a and the second external electrode 2b of the individual semiconductor device 1 are dipped into not shown plating liquid in a plating bath, so that the plating films 4 are formed on five surfaces defining each electrode 2a (2b). As for this plating, either a single layer film or multilayer films with silver, solder (Sn+Pb), etc. may be deposited on each surface of the electrodes 2a, 2b. If solder plating is applied on the outermost surface of the electrode, then it is possible to improve the device's wettability with solder used in connecting the device 1 with a substrate (not shown).

Thus, Owing to the provision of the semiconductor device 1 where the semiconductor chip 5 is sealed up with the sealing member 3 and additionally, the chip's polar surfaces are electrically connected to the external electrodes 2 through the conductive members 6, it becomes possible to provide a semiconductor device and its manufacturing method both capable of ensuring high reliability while improving its electrical characteristics with the structure requiring no bonding wires and also improving the productivity with raised process yield.

Thus, by using the sheet-shaped sealing material 3′ fusible at a predetermined temperature, due to its flexibility, it is possible to prevent the semiconductor chip 5 from being damaged in manufacturing the semiconductor device 1. Additionally, as the conductive members 6 are disposed in the through-holes 3a of the sealing material 3′ in process of manufacturing the semiconductor device 1, the adjustment in size of the through-holes 3a allows the character of the device 1 to be controlled in terms of its conductive path for current and the wiring length to thereby improve the electrical characteristics. According to the above-mentioned manufacturing method, since the conductive members and the external electrodes can be together connected to a large number of semiconductor tips at a time, it is possible to improve the productivity for semiconductor devices with a shortened manufacturing time.

Besides the above-mentioned effects, the welding state of solder in mounting the semiconductor device 1 on a substrate is visible since the semiconductor device 1 of the first embodiment has a pair of electrodes each consisting of five surfaces. Thus, as the structure of the semiconductor device 1 allows solder to constitute a sufficient fillet between the external electrode and the substrate, it is possible to prevent the semiconductor device 1 from being damaged due to an external force such as impact.

### 2nd. Embodiment

The second embodiment of the present invention will be described below. In the second embodiment, elements identical to those of the first embodiment are indicated with the same reference numerals and their overlapping descriptions are eliminated.

The second embodiment is directed to prevention of a breakage of the semiconductor device originating in one boundary between the semiconductor chip and the conductive member and another boundary between the conductive member and the external electrode at the package reliability evaluation test (e.g. share test) or at a substrate's bending due to heat of use.

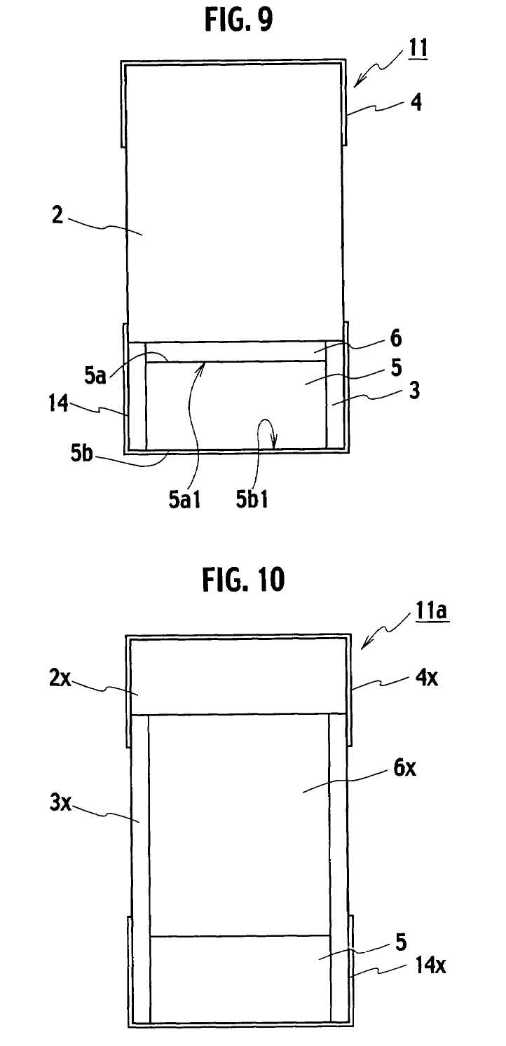

FIG. 9 is a sectional view of a semiconductor device 11 in the second embodiment of the present invention. While the above-mentioned semiconductor device 1 of the first embodiment includes the semiconductor chip 5 interposed between the first external electrode 2a and the second external electrode 2b, the semiconductor device 11 of the second embodiment has the semiconductor chip 5 shifted to one side of the device 11 with the formation of the external electrode 2 exceeding a center of the device 11 in the longitudinal direction.

In the semiconductor chip 5, the first pole 5a1 is arranged on the first surface 5a. The first surface 5a is connected to the external electrode 2 through the conductive member 6. The external electrode 2 is partially coated with the plating film 4. The semiconductor chip 5 and the conductive member 6 are sealed up with the sealing member 3. In order to accomplish total contact of the conductive member 6 with the whole first surface 5a of the semiconductor chip 5, the contact surface of the member 6 for connection with the first surface 5a has an area equal to the area of the first surface 5a of the chip 5.

On the other hand, the semiconductor chip 5 has the second pole 5b1 arranged on the second surface 5b so as to oppose the first pole 5a1. The second pole 5b1 is not connected to the conductive member 6 and the external electrode 2. Instead, plating is directly applied on the second pole 5b1 and the sealing member 3 enclosing the semiconductor chip 5.

Consequently, as shown in FIG. 9, a plating film 14 is formed on the second surface 5b and the sealing member 3 while exceeding a joint surface between the external electrode 2 and the sealing member 3 (or the conductive member 6). In this way, one boundary between the semiconductor chip 5 and the conductive member 6 and another boundary between the conductive member 6 and the external electrode 2 are together protected by the plating film 14.

FIG. 10 shows a semiconductor device 11a in a modification of the semiconductor device 11 of FIG. 9. In common, the semiconductor device 11a has the semiconductor chip 5 shifted on one side of the device 11a in the longitudinal direction. The semiconductor device 11a differs from the afore-mentioned device 11 in that a conductive member 6x is shaped so as to exceed the intermediate portion of the device 11a in the longitudinal direction. In return for the formation, the semiconductor device 11a is provided with a small external electrode 2x in comparison with the previous external electrode 2 of the semiconductor device 11. Correspondingly, a sealing member 3x is also elongated in the longitudinal direction of the device 11a.

In the semiconductor device 11a, a plating film 4x for the external electrode 2x is formed so as to cover the boundary between the conductive member 6x and the external electrode 2x, while another plating film 14x for the second surface 5b of the semiconductor chip 5 is formed so as to cover the boundary between the semiconductor chip 5 and the conductive member 6x.

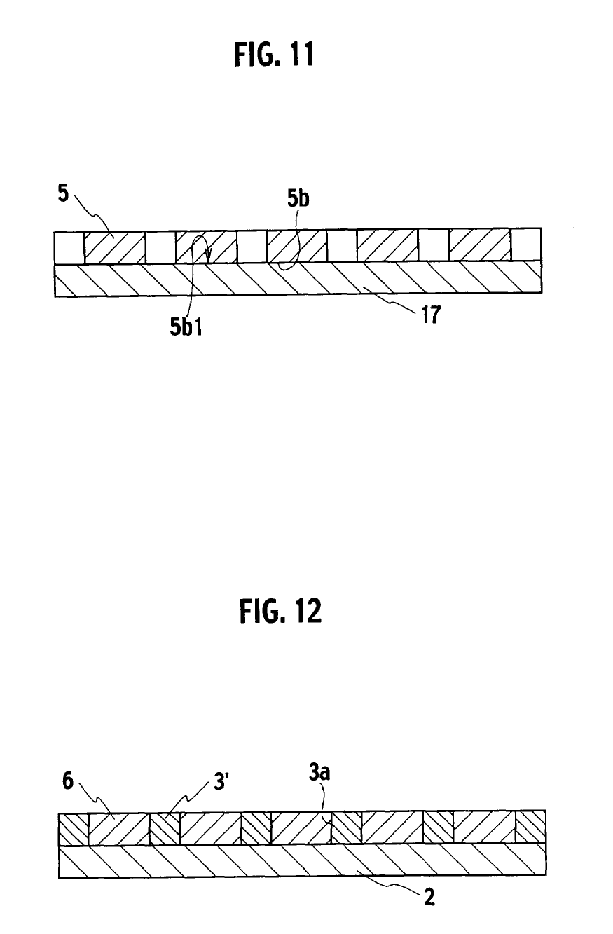

The manufacturing method of the semiconductor device 11 of the second embodiment will be described with reference to FIGS. 11 to 13.

First of all, a plate-shaped stage 17 is prepared and successively, a plurality of semiconductor chips 5 are mounted on the stage 17 so that the second pole 5b of each second surface 5b abuts on a surface of the stage 17, as shown in FIG. 11. The semiconductor chips 5 are separated from each other at regular intervals in order to receive sealing material at a later-mentioned manufacturing process. The interval between the adjoining semiconductor chips 5 may be optionally determined in consideration of the quantity of the sealing material required for desired electrical characteristics. In another process, an external electrode 2 is produced with the sheet-shaped sealing material 3′ having the through-holes 3a, as shown in FIG. 12. The through-holes 3a are filled up with the conductive members 6. This external electrode 2 is identical to the external electrode 2 produced by the manufacturing method of the first embodiment.

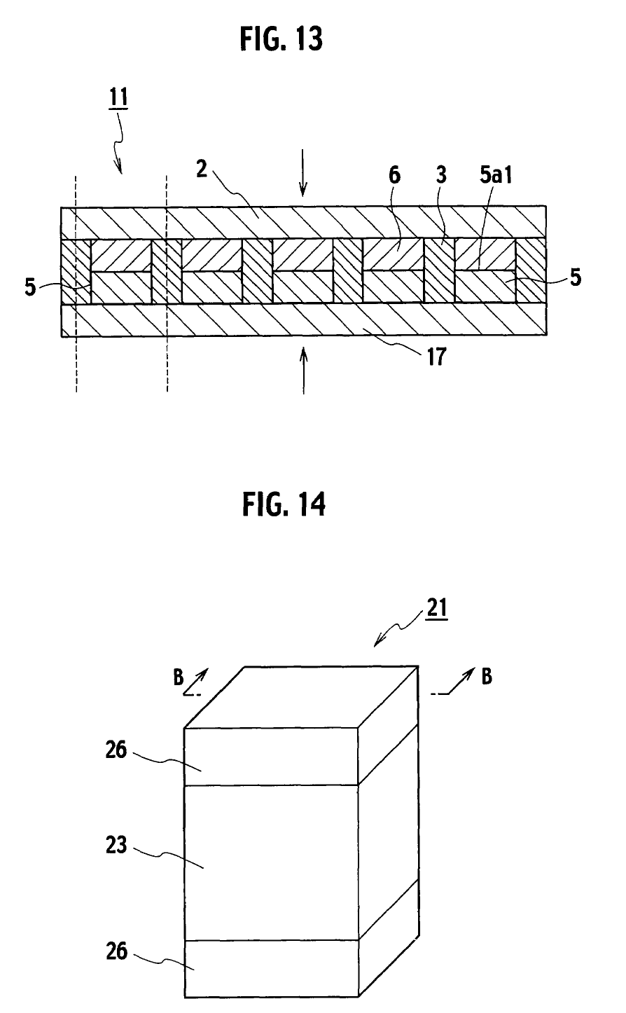

Next, reversing the assembly of FIG. 12, it is mounted on the assembly of FIG. 11 so that the conductive members 6 on the external electrode 2 abut on the first poles 5a1 on the first surfaces 5a of the semiconductor chips 5, as shown in FIG. 13. Then, as shown with arrows in the figure, pressure with heat is applied on the external electrode 2 and the stage 17 interposing the semiconductor chips 5. Consequently, the sheet-shaped sealing materials 3′ are molten to fill respective spaces each between the adjoining semiconductor chips 5. By further continuing the heating, the filled sealing materials 3′ are hardened. Simultaneously, the conductive members 6 are also hardened.

After the sealing materials 3′ are hardened, the stage 17 is removed from the second surfaces 5b of the semiconductor chips 5. Successively, the resultant integrated body (assembly) is diced, between the adjoining semiconductor chips 5, by a dicing cutter thinner than an interval of the adjoining semiconductor chips 5, as shown with broken lines of FIG. 13. Further, the plating is applied to the individual semiconductor device 1 so as to cover the external electrode 2 and the second surface 5b of the semiconductor chip 5 (see FIGS. 9 and 10). As for the plating, the resultant plating film formed on the external electrode 2 and the second surface 5b may comprise either a single layer film or multilayer films. Thus, the semiconductor device 11 (11a) is produced with electrodes each having five surfaces, as similar to the first embodiment.

Therefore, also in the second embodiment, it is possible to provide a semiconductor device and its manufacturing method both capable of ensuring high reliability while improving its electrical characteristics with the structure requiring no bonding wires and also improving the productivity with raised process yield.

In addition to all effects by the first embodiment, as the semiconductor device 11 (11a) of the second embodiment has the semiconductor chip 5 shifted on one side of the device in the longitudinal direction, it is possible to prevent the semiconductor chip 5 from being broken, for example, its breakage originating in one boundary between the semiconductor chip and the conductive member and another boundary between the conductive member and the external electrode at the package reliability evaluation test (e.g. share test) or at a substrate's bending due to heat of use. Additionally, the deposition of the plating films 4, 14 (4x, 14x) covering these boundaries can reinforce the prevention of a breakage of the semiconductor chip 5.

### 3^{rd}. Embodiment

The third embodiment of the present invention will be described below. In the third embodiment, elements identical to those of the first and the second embodiments are indicated with the same reference numerals and their overlapping descriptions are eliminated.

According to the third embodiment, a semiconductor device 21 is provided in the form of a substantially-rectangular parallelepiped, as shown in FIG. 14. The difference between the third embodiment and the previous embodiments resides in that the semiconductor device 21 is provided with no external electrode but conductive members 26 serving as the external electrodes.

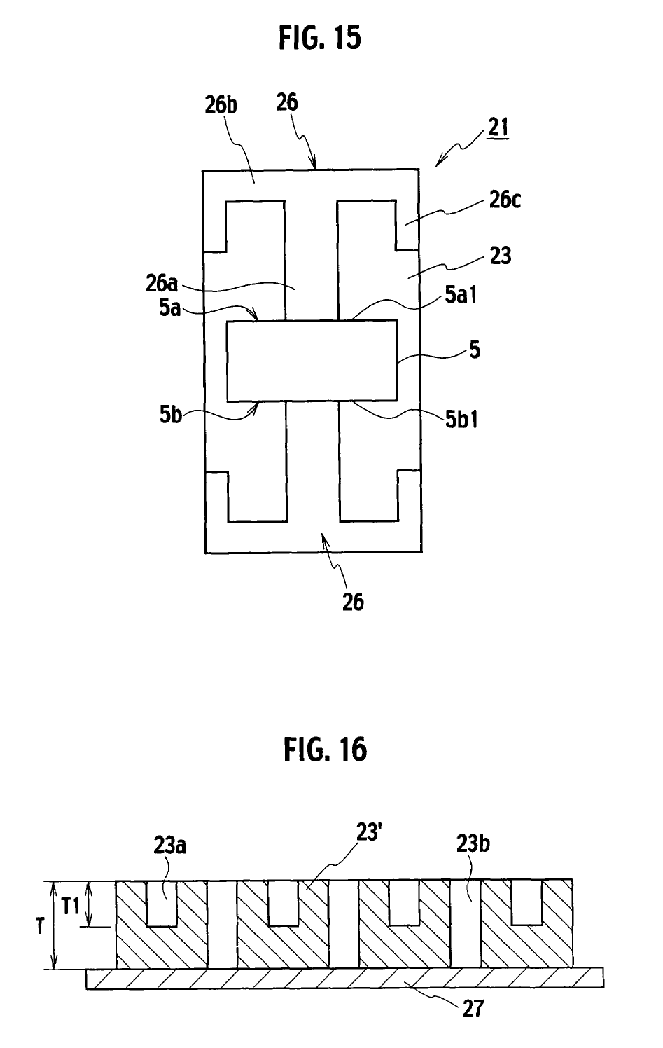

FIG. 15 is a sectional view of the semiconductor device 21, taken along a line B-B of FIG. 14. The semiconductor device 21 comprises the semiconductor chip 5 at the substantial center of the device 21, a pair of conductive members 26, 26 connected to the first surface 5a having the first pole 5a1 of the chip 5 and the second surface 5b having the second pole 5b1 and a sealing member 23, eliminating the above-mentioned external electrode 2.

Each conductive member 26 has one end in contact with the first pole 5a1 or the second pole 5b1, whose area is smaller than the area of the first surface 5a of the chip 5 or the second surface 5b, and the other end whose area is larger than the area of the first surface 5a of the chip 5 or the second surface 5b. That is, as shown in FIG. 15, the conductive member 26 is substantial-T shaped in section. In the conductive member 26, its center vertical shaft 26a has one end connected to the first surface 5a of the chip 5 or the second surface 5b. The other end of the vertical shaft 26a forms a horizontal shaft 26b whose area is larger than the section of the vertical shaft 26a connected to the first surface 5a or the second surface 5b. The horizontal shaft 26b is connected, on both ends in the horizontal direction, with other vertical shafts 26c each shorter than the center vertical shaft 26b. The horizontal shaft 26b and the short vertical shafts 26c are together exposed to the surface of the semiconductor device 21, so that the conductive member 26 functions as the above-mentioned electrode having five surfaces.

As shown in FIG. 15, the sealing member 23 seals a space defined between the first surface 5a of the semiconductor chip 5 and the horizontal shaft 26b of the conductive member 26 and also another space defined between the second surface 5b and the horizontal shaft 26b of the other conductive member 26. In addition, the sealing member 23 also seals intervals each between the leading ends of the opposing short vertical shafts 26c, 26c in the longitudinal direction. The exposed surfaces of the short vertical shafts 26c are flush with the outside surfaces of the sealing material 23, forming the outside surfaces of the semiconductor device 21 of the embodiment.

The method of the semiconductor device 21 of the third embodiment will be described with reference to FIGS. 16 to 18.

First, as shown in FIG. 16, a sheet-shaped sealing material 23′ is mounted on a dicing sheet 27 and further, grooves for the short shafts 26 are formed at regular intervals in a lattice manner by means of dicing. That is, a plurality of grooves 23a with a height T1 each are formed in the material 23 by using a dicing blade (not shown). The height T1 corresponds to the length of the short vertical shaft 26 of the conductive member 26.

Next, using drill or laser, a plurality of through-holes 23b are formed in the sealing material 23′ so as to center on respective midpoints between the adjoining grooves 23a, 23a (see FIG. 16). Each through-hole 23b has a height T corresponding to the length of the vertical shaft 23a of the conductive member 26. The height T of the sealing material 23′ may be determined in consideration of the size of the semiconductor device 21 and a wiring distance for current. In this way, the sealing material 23′ is provided with a plurality of recesses as shown in FIG. 16. In this manufacturing method, several sealing materials 23′ are produced.

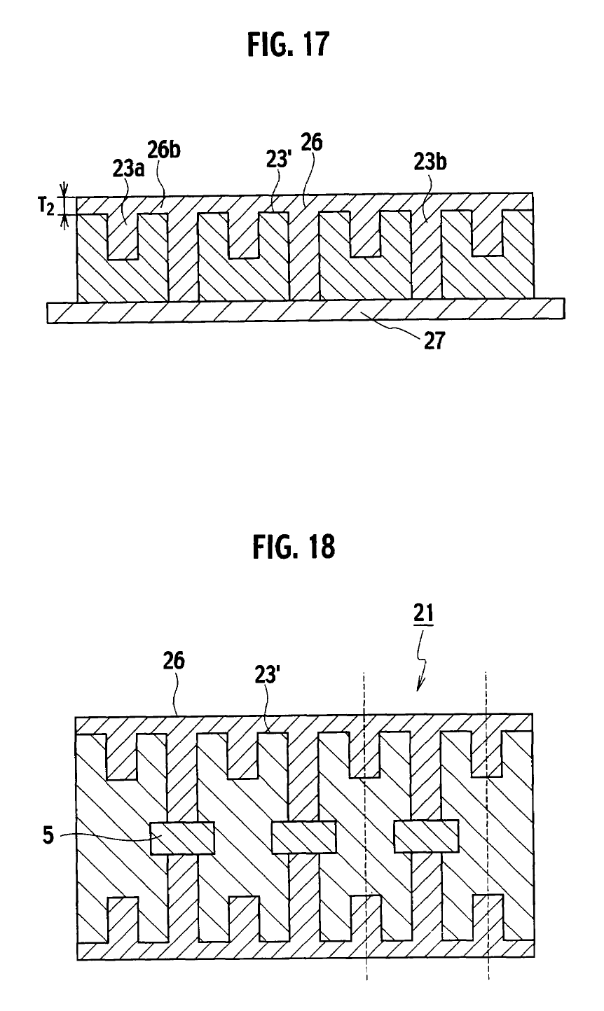

Then, as shown in FIG. 17, the grooves 23a and the through-holes 23b are filled up with conductive material. Further, the conductive material is applied on respective surfaces of the sealing material 23′ in non-contact with the dicing sheet 27 while getting a uniform height T2 lined up. This height T2 corresponds to a thickness of the horizontal shaft 26b of the conductive member 26. Thereafter, the conductive material is hardened to form the conductive member 26. Next, the dicing sheet 27 is removed from a combination of the sealing material 23′ and the conductive member 26 (note: combination referred to as “component” hereinafter). Such a component is prepared in plural.

Successively, the component after the removal of the dicing sheet 27 is further reversed so that the sealing material's surface (in previous contact with the sheet 27) directs upwards. Note, the so-reversed component will be referred to as “second component 28b” after. The semiconductor tips 5 are mounted on the second component 28, at respective positions of the through-holes 23b. It is noted that the above vertical shaft 26a of the conductive member 26 is formed in each through-hole 23b. In arrangement, each of the semiconductor tips 5 is positioned so that the second surface 5b abuts on the leading end of the vertical shaft 26a.

Next, another component (referred to as “first component 28a” after) is prepared and further laid on the semiconductor tips 5 mounted on the second component 28b. In other words, the first component 28 is mounted on the semiconductor tips 5 in a manner that each vertical shaft 26b of the conductive member 26 abuts on each first surface 5a of the semiconductor tips 5. Consequently, the semiconductor tips 5 are sandwiched between the first component 28a and the second component 28b.

Finally, pressure with heat is applied on the first component 28a and the second component 28b interposing the semiconductor tips 5 therebetween to melt the sealing material 23′. FIG. 18 shows a state where the sheet-shaped sealing material 23′ is molten to enclose the semiconductor tips 5 therein. Thereafter, the resultant integrated body (assembly) is diced, at the center of each groove 23a between the adjoining semiconductor chips 5, by a dicing cutter thinner than the groove 23a, completing the semiconductor device 21 of FIG. 15.

Therefore, also in the third embodiment, it is possible to provide a semiconductor device and its manufacturing method both capable of ensuring high reliability while improving its electrical characteristics with the structure requiring no bonding wires and also improving the productivity with raised process yield.

Additionally, since the conductive members 26 in the semiconductor device 21 serve as the previously-mentioned external electrodes, it is possible to avoid an omnibus dicing of different materials of metal (i.e. external electrodes) and resin (sealing material), which is generally regarded as a difficult machining, allowing the productivity to be improved due to the easiness in the manufacturing process of semiconductor devices.

### 4^{th}. Embodiment

The fourth embodiment of the present invention will be described below. Also in the fourth embodiment, elements identical to those of the first to the third embodiments are indicated with the same reference numerals and their overlapping descriptions are eliminated.

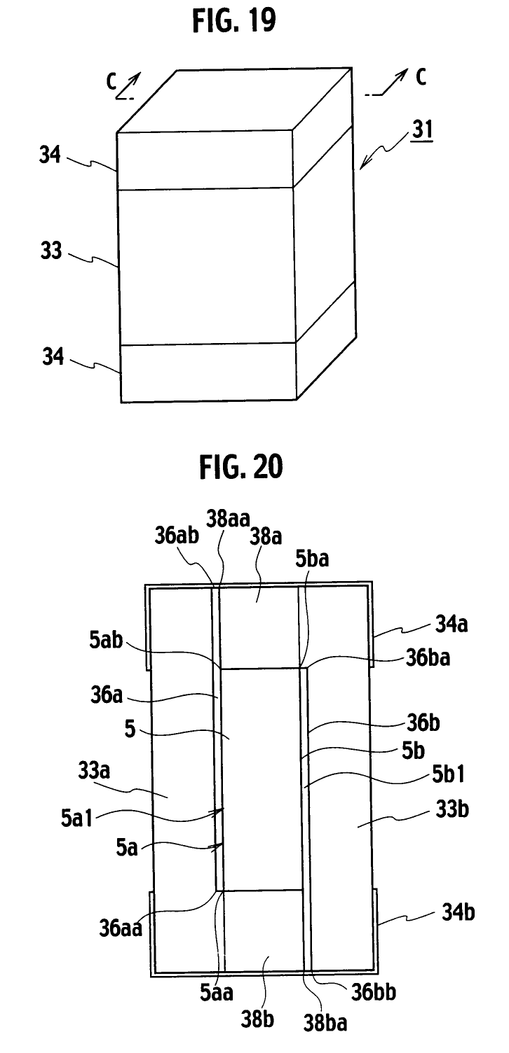

According to the fourth embodiment, a semiconductor device 31 is provided in the form of a substantially-rectangular parallelepiped, as shown in FIG. 19. The semiconductor tip 5 (not shown) is sealed up with sealing materials 33 (33a, 33b). On both sides of the device 31 in the longitudinal direction, a pair of plating films 34 (34a, 34b) are formed as external electrodes.

FIG. 20 is a sectional view of the semiconductor device 31, taken along a line C-C of FIG. 19. The difference between the fourth embodiment and the previous embodiments resides in the orientation of the semiconductor tip 5 in the longitudinal direction of the device 31. In detail, the semiconductor tip 5 is sealed up so that its longitudinal direction is parallel with the longitudinal direction of the device 31, making an angle of 90 degrees with the direction of the semiconductor tip 5 in the first to the third embodiments.

In the semiconductor tip 5, the first pole 5a1 is arranged on the first surface 5a, while the second pole 5b1 is arranged on the second surface 5b. All surfaces of the chip 5 but the surfaces 5a, 5b are sealed up with a sealing material 38. The sealing material 38 is formed with a length equal to an interval between the first surface 5a and the second surface 5b. As shown in FIG. 22 (details mentioned later), a sealing material's surface perpendicular to its surface abutting on the semiconductor tip 5 constitutes an identical plane together with the first surface 5a and the second surface 5b.

Conductive members 36 (36a, 36b) are connected to the first surface 5a and the second surface 5b of the chip 5. In the conductive members 36, a first conductive member 36a is connected to the overall first surface 5a. In detail, as shown in FIG. 20, the first conductive member 36a is formed so as to extend from one end 5aa of the first surface 5a to the surface of a sealing material 38a sealing the semiconductor chip 5 through the other end 5ab of the first surface 5a. More in detail, the first conductive member 36a terminates at an end of one surface of the sealing material 36a opposed to the other surface in contact with the chip 5. Note, this end will be referred to as “terminal end 38aa” after. While, the other end of the first conductive member 36a will be referred to as “leading end 36ab” after.

On the other hand, a second conductive member 36b is connected to the overall second surface 5b so as to align its one end 36ba (of the member 36b) with an end 5ba of the second surface 5b. That is, as shown in FIG. 20, the second conductive member 36b is connected to the overall second surface 5b while originating in the end 5ba of the second surface 5b. It is noted that the end 5ba of the second surface 5b is in diagonal with the end 5aa of the first surface 5a. More in detail, the second conductive member 36b is formed so as to extend from the end 5ba of the second surface 5b to the surface of another sealing material 38b sealing the semiconductor chip 5 through the other end 5bb of the second surface 5b. Similarly, the second conductive member 36b terminates at an end of one surface of the sealing material 36b opposed to the other surface in contact with the chip 5. Note, this end will be referred to as “terminal end 38ba” after. While, the other end of the second conductive member 36b will be referred to as “leading end 36ab” after. In summary, the conductive members 36a, 36b are connected to the semiconductor chip 5 so as to extend from respective origins in the opposite direction to each other while interposing the semiconductor tip 5 (alternate arrangement).

A surface of the first conductive member 36a and a surface of the sealing material 38b, both surfaces of which constitute an identical plane with the first surface 5a of the chip 5, are together sealed up with a first sealing member 33a. Similarly, a surface of the second conductive member 36b and a surface of the sealing material 38a, both surfaces of which constitute an identical plane with the second surface 5b of the chip 5, are together sealed up with a second sealing member 33b.

In the later-mentioned manufacturing method, by a dicing process, the semiconductor devices are individualized in a manner that all of the first sealing member 33a, the other end 36ab of the first conductive member 36a, the sealing material 38a and the second sealing member 33b constitute an identical plane. The first plating film 34a is formed on such an identical plane.

By the dicing process, similarly, the semiconductor devices are also individualized in a manner that all of the second sealing member 33b, the other end 36bb of the second conductive member 36b, the sealing member 38b and the first sheet-shaped seaming material 33a constitute another identical plane. The second plating film 34b is formed on the identical plane. Thus, the semiconductor device 31 of the embodiment is formed, on both sides in the longitudinal direction, with the first plating film 34a and the second plating film 34b. When these plating films 34a, 35b are connected to a substrate through solders, the packaging of the semiconductor device 31 onto the substrate is accomplished. In the so-assembled semiconductor device 31, foe example, there is a current flow from the first plating film 34a to the second plating film 34b through the intermediary of the other end 36ab of the first conductive member 36a, the first conductive member 36a, the semiconductor tip 5, the second conductive member 36b and the other end 36bb of the second conductive member 36b, in this order.

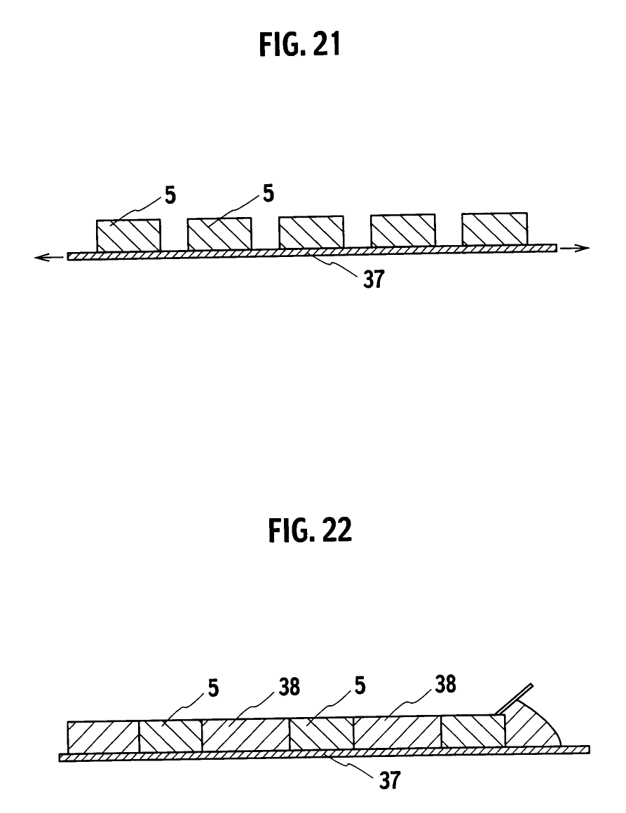

The manufacturing method of the semiconductor device 32 of the fourth embodiment will be described with reference to FIGS. 21 to 25.

As shown in FIG. 21, if pulling a dicing sheet 37 having a plurality of semiconductor tips 5 mounted thereon in the directions of arrows, then an interval between the adjoining semiconductor chips 5 increases. In this state, it is performed to fill a sealing material 38 in respective gaps each defined between the adjoining semiconductor tips 5 and further harden the filled sealing material 38 in the gaps. In connection with this procedure, FIG. 22 illustrates one method of filling the sealing material 38 in the gaps between the semiconductor tips 5 by first bringing the material 38 to bear on the semiconductor tips 5 and subsequently applying a squeegee on respective surfaces of the chips 5 in non-contact with the dicing sheet 37. Besides the above method, alternatively, the gaps may be filled up with sealing material 38 by using a printing method or the like. As for the former method, due to the adoption of squeeze, the thickness (height) of the sealing material 38 becomes equal to the thickness (height) of the semiconductor tips 5.

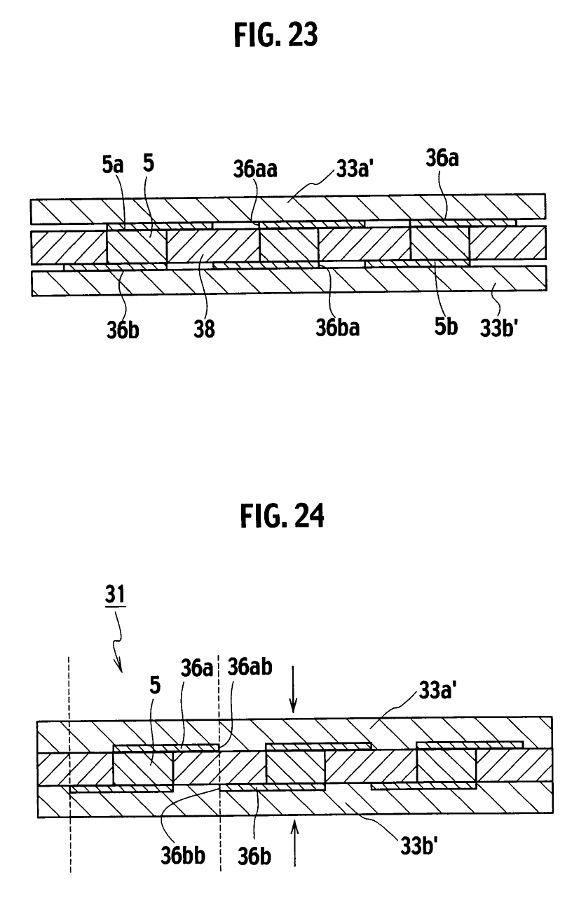

While, in another process, the conductive members 36 are formed, at regular intervals, on a sheet-shaped sealing material 33′ by the printing method etc. Next, a sheet of FIG. 22 composed of the semiconductor tips 5 and the sealing material 38 (but the dicing sheet 37 removed in advance) is mounted on the conductive members 36 so that respective surfaces of the chips 5 abut on the conductive member 36 respectively (see FIG. 23).

In mounting the semiconductor tip 5 on the second conductive member 36b, the positioning of both elements is carried out so as to connect the second conductive member 36b to the whole second surface 5b of the chip 5 and further align a chip's end abutting on the sealing material 38 with an end 36ba of the second conductive member 36b. With this positioning, not only the semiconductor tip 5 but a part of the sealing material 38 abutting on the other end of the chip 5 is connected onto the second conductive member 36b. Note, a sealing material's area in non-contact with the second conductive member 36b might produce a space against a second sheet-shaped sealing material 33b′. Nevertheless, this space would be sealed up with the second sheet-shaped sealing material 33b′ that has been molten and subsequently hardened.

Next, the first conductive member 36a is mounted on each first surface 5a of the semiconductor tips 5 for electrical connection, as shown in FIG. 23. Then, similarly, the positioning of both elements is carried out so as to connect the first conductive member 36a to the whole first surface 5a of the chip 5 and further align a chip's end abutting on the sealing material 38 with an end 36aa of the first conductive member 36a. Note, the chip's end in this electrical connection corresponds to the afore-mentioned chip's end in the above-mentioned electrical connection between the second surface 5b of the tip 5 and the second conductive member 36b. In this way, the first and the second conductive members 36a, 36b are connected to the first and the second surface 5a, 5b of the semiconductor chip 5 so as to extend from respective origins in the opposite direction to each other while interposing the semiconductor tip 5 (alternate arrangement).

Then, as shown with arrows of FIG. 24, pressure with heat is applied on the first sheet-shaped sealing material 33a′ and the second sheet-shaped sealing material 33b′ interposing the semiconductor chips 5. By this operation, the sheet-shaped sealing materials 33′ (33a′, 33b′) are molten and subsequently hardened. Thereafter, the resultant integrated body (assembly) is diced along broken lines of FIG. 24.

The dicing is carried out so as to expose the end 36ab of the first conductive member 36a and the end 36bb of the second conductive member 36b for the purpose of accomplishing the subsequent electrical connection between the ends of the conductive members 36 and the subsequent plating films 34. On completion of the dicing process, the so-individualized semiconductor device 31 is transferred to a plating process where the plating films 34 are formed so as to cover the sealing members 33a, 33b, the conductive members 36 and the sealing materials 38. In this way, the semiconductor device 31 of FIG. 20 is completed.

Therefore, also in the third embodiment, it is possible to provide a semiconductor device and its manufacturing method both capable of ensuring high reliability while improving its electrical characteristics with the structure requiring no bonding wires and also improving the productivity with raised process yield.

In addition, as the semiconductor device 31 of the fourth embodiment encloses the semiconductor chip 5 orientated so that its longitudinal direction is parallel with the longitudinal direction of the device 31, it is possible to prevent the semiconductor chip 5 from being broken, for example, its breakage originating in one boundary between the semiconductor chip and the conductive member and another boundary between the conductive member and the external electrode at the package reliability evaluation test (e.g. share test) or at a substrate's bending due to heat of use.

### 5^{th} Embodiment

The fifth embodiment of the present invention will be described below. Also in the fifth embodiment, elements identical to those of the first to the fourth embodiments are indicated with the same reference numerals and their overlapping descriptions are eliminated.

According to the fifth embodiment, a semiconductor device 41 is provided in the form of a substantially-rectangular parallelepiped, as shown in FIG. 25. The semiconductor tip 5 (not shown) is sealed up with sealing members 43 (43a, 43b). On both sides of the device 41 in the longitudinal direction, a pair of plating films 44 (44a, 44b) are formed as external electrodes.

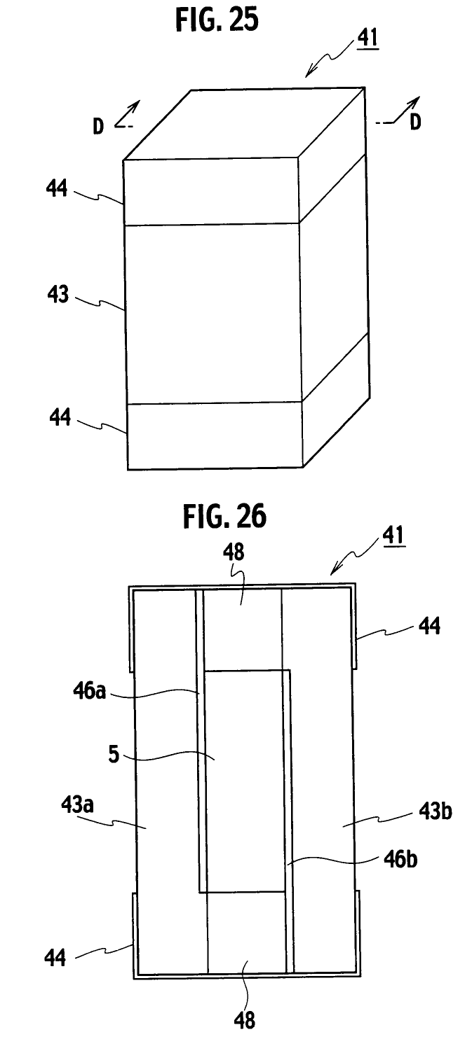

FIG. 26 is a sectional view of the semiconductor device 41, taken along a line D-D of FIG. 25. In the structure, the semiconductor device 41 is similar to the semiconductor device 31 of the fourth embodiment.

The difference between the fifth embodiment and the fourth embodiment resides in that the conductive members are formed by metal foils. The fifth embodiment is directed to a prevention of the conductive member from protruding into a space to be filled up with the sealing material 33 in the heating process under pressure. In order to ensure a conductive path, the fifth embodiment adopts the metal foils in place of the conductive members 36 of the fourth embodiment.

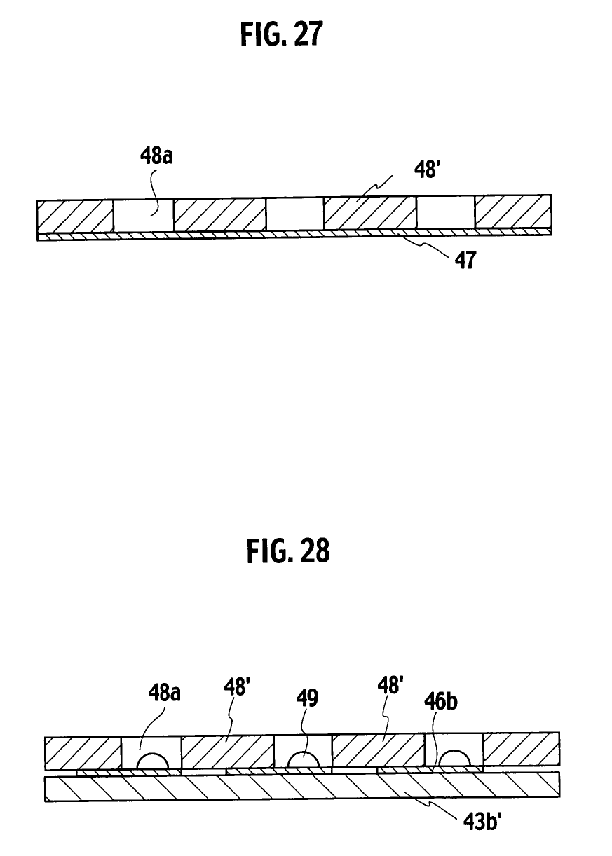

The manufacturing method of the semiconductor device 41 of the fourth embodiment will be described with reference to FIGS. 27 to 31.

First of all, metal foils are formed at regular intervals on a third sheet-shaped sealing material although they are not shown in the figures. The formation of the metal foils may be accomplished by first evaporating a metal film on the sealing material and successively etching the metal film to the metal foils.

In another process, as shown in FIG. 27, another third sheet-shaped sealing material 48′ is press-fitted on a dicing sheet 47 temporarily. Subsequently, a plurality of through-holes 48a for the semiconductor chips 5 are formed in the sealing material 48′.

Next, preparing the former sheet-shaped sealing material having the metal foils etched, conductive adhesives 49 are arranged on the respective metal foils 46b on a sheet-shaped sealing material 43b′, at respective positions for mounting the semiconductor chips 5.

Removing the sealing material 43b from the dicing sheet 47, the resultant sealing material 43b′ (without the dicing sheet 47) is mounted on the metal foils 46b on the above the sheet-shaped sealing material 43b′, as shown in FIG. 28. In detail, the sealing material 48′ is mounted on the sheet-shaped sealing material 43b′ so as to align one end of each metal foil 46b with a side wall of the through-hole 48a in sectional view. Due to this positioning, when the semiconductor chips 5 are inserted into the through-holes 48a, one side surface of each chip 5 in the shortitudinal direction is aligned with one end of the metal foil 46b, forming an identical plane. Additionally, the above conductive adhesives 49 are positioned in the vicinity of respective centers of the through-holes 48a.

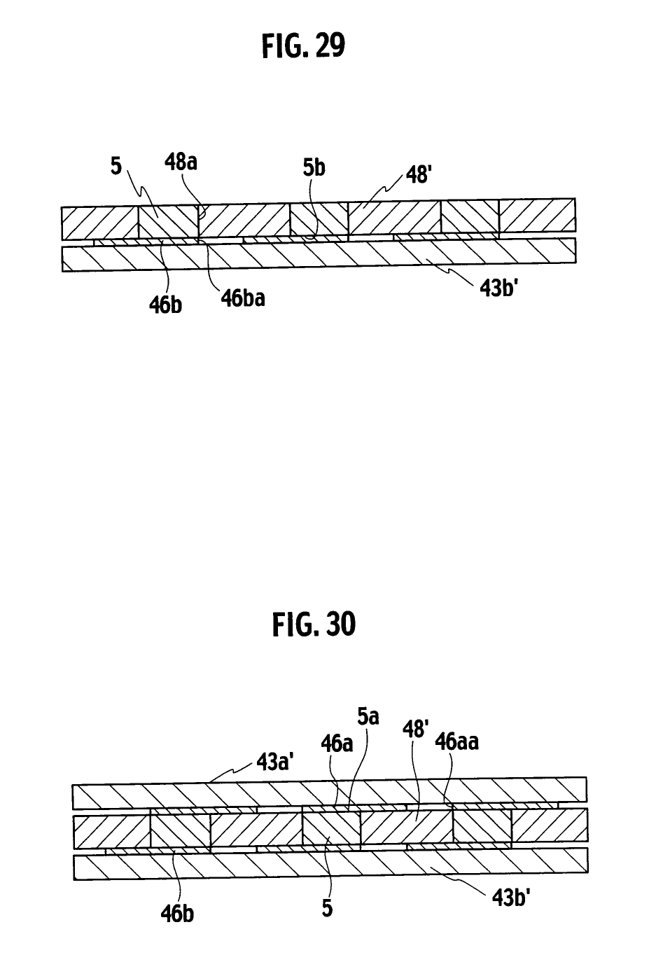

Next, as shown in FIG. 29, the semiconductor chips 5 are arranged in the through-holes 48 so that the second surfaces 5b make full contact with the metal foils 46b respectively. Thus, in this state, each metal foil 46 makes contact with the whole second surface 5b of the semiconductor chip 5, while one end of the chip 5 abutting on the sealing material 48′ is aligned with an end 46ba of the metal foil 46b. With this positioning, not only the semiconductor tip 5 but a part of the sealing material 48′ abutting on the other end of the chip 5 is connected onto the metal foil 46b. Note, a sealing material's area in non-contact with the metal foil 46b might produce a space against the second sheet-shaped sealing material 43b′. Nevertheless, this space would be sealed up with the second sheet-shaped sealing material 43b′ that has been molten and subsequently hardened.

Furthermore, another sheet-shaped sealing material 43a′ having the conductive adhesives 49 mounted on the metal foils 46a is prepared and mounted on the assembly of FIG. 29 so that the conductive adhesives 49 make contact with the first surfaces 5a of the semiconductor tips 5, as shown in FIG. 30. Then, similarly, the positioning of both elements is carried out so as to connect the metal foil 46a to the whole first surface 5a of the chip 5 and further align a chip's end abutting on the sealing material 48′ with an end 46aa of the metal foil 46a. Note, the chip's end in this electrical connection corresponds to the afore-mentioned chip's end in the above-mentioned electrical connection between the second surface 5b of the tip 5 and the metal foil 46b. In this way, the metal foils 46a, 46b are connected to the first and the second surface 5a, 5b of the semiconductor chip 5 so as to extend from respective origins in the opposite direction to each other while interposing the semiconductor tip 5 (alternate arrangement).

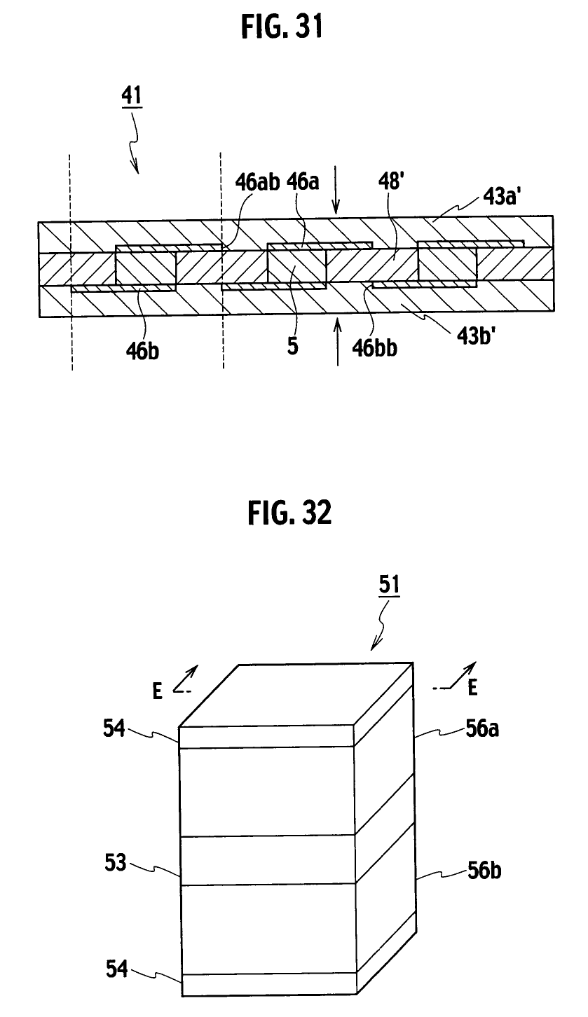

Then, as shown with arrows of FIG. 31, pressure with heat is applied on the first sheet-shaped sealing material 43a′ and the second sheet-shaped sealing material 43b′ interposing the semiconductor chips 5. By this operation, the sheet-shaped sealing materials 43a′, 43b′ are molten and subsequently hardened. Thereafter, the resultant integrated body (assembly) is diced along broken lines of FIG. 31.

The dicing is carried out so as to expose the end 46ab of the metal foil 46a and the end 46bb of the metal foil 46b for the purpose of accomplishing the subsequent electrical connection between the ends of these metal foils 46a, 46b and the subsequent plating films 44. On completion of the dicing process, the so-individualized semiconductor device 41 is transferred to a plating process where the plating films 44 are formed so as to cover the sealing member 43a, 43b, the metal foils 46a, 46b and the sealing members 48. In this way, the semiconductor device 41 of FIG. 26 is completed.

Therefore, also in the third embodiment, it is possible to provide a semiconductor device and its manufacturing method both capable of ensuring high reliability while improving its electrical characteristics with the structure requiring no bonding wires and also improving the productivity with raised process yield.

In addition, as the semiconductor device 41 of the fifth embodiment encloses the semiconductor chip 5 orientated so that its longitudinal direction is parallel with the longitudinal direction of the device 41, it is possible to prevent the semiconductor chip 5 from being broken, for example, its breakage originating in one boundary between the semiconductor chip and the conductive member and another boundary between the conductive member and the external electrode at the package reliability evaluation test (e.g. share test) or at a substrate's bending due to heat of use. Additionally, owing to the provision of the above-mentioned manufacturing method, it is possible to eliminate the process of temporarily hardening the sheet-shaped sealing material enclosing the circumference of the semiconductor device, allowing the productivity of the semiconductor devices to be improved.

### 6^{th}. Embodiment

The sixth embodiment of the present invention will be described below. Also in the sixth embodiment, elements identical to those of the first to the fifth embodiments are indicated with the same reference numerals and their overlapping descriptions are eliminated.

The difference between the sixth embodiment and the first embodiment resides in that no conductive member is used to connect the semiconductor chip 5 to one external electrode 2.

For example, in the semiconductor device 1 of the first embodiment, the conductive member 6 such as silver (Ag) or copper (Cu) paste (subsequently hardened) is used to connect the semiconductor chip 5 to the external electrode 2.

Generally, the conductive member 6 contains binder resin for enhancing adhesion between the pole of the semiconductor chip 5 and the external electrode 2.

On the contrary, the sixth embodiment of the present invention is directed to a metal-to-metal joint between the first pole 5a1 of the semiconductor chip 5 and the external electrode 52a without using the above conductive member 6, for the purpose of preventing an exfoliation of adhesive boundary faces by the conductive member 6.

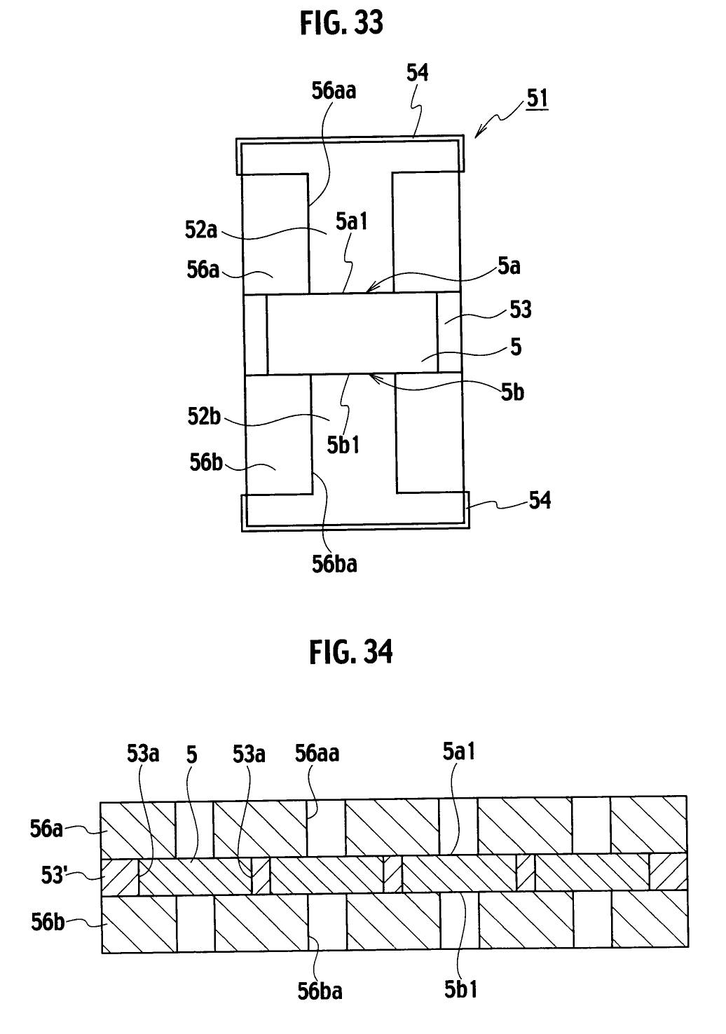

According to the sixth embodiment, a semiconductor device 51 is provided in the form of a substantially-rectangular parallelepiped, as shown in FIG. 32. The semiconductor tip 5 (not shown) is sealed up with a sealing member 53. The sealing member 53 is interposed between a first resin substrate 56a and a second resin substrate 56b both of which will be generically referred to as “resin substrates 56” after. On both sides of the device 51 in the longitudinal direction, a first external electrode 52a and a second external electrode 52b (see FIG. 33) which will be generically referred to as “external electrodes 52” after, are arranged and also coated with a pair of plating films 54 respectively, thereby forming a pair of electrodes each having five surfaces.

FIG. 33 is a sectional view of the semiconductor device 51, taken along a line E-E of FIG. 32. The semiconductor device 51 is provided, at a substantial center in the longitudinal direction, with the semiconductor chip 5. The semiconductor chip 5 comprises a first surface 5a having a first pole 5a1, a second surface 5b having a second pole 5b1 and four surfaces sealed up with the sealing member 53.

In the semiconductor chip 5, the first pole 5a1 is connected to an end of the first external electrode 52a electrically. The first external electrode 52a is provided by applying plating on a through-hole 56aa formed in the first resin substrate 55a. The above-mentioned metal-to-metal joint is realized between the first external electrode 52a and the first pole 5a1 through this plating. The plating may be provided by means of either electrolytic plating or electroless plating. In the sixth embodiment, copper (Cu) is employed as the external electrode. However, the plating material is not limited to copper (Cu) only and it may be replaced by other metals, for example, gold (Au), nickel (Ni), tin (Sn) or the like.

When the though-hole 56aa is filled up with the plating metal, the first external electrode 52a has one end (or leading end) connected to the first pole 5a1. On the other hand, the other end of the electrode 52a is formed since the plating filling the through-hole 56aa is further deposited on an upper face of the first resin substrate 56a (i.e. one substrate's surface opposed to the other surface abutting on the surface 5a of the semiconductor chip 5 and the sealing member 53). Therefore, the other end of the electrode 52 has an area larger than that of the leading end of the electrode 52 or an area of the first surface 5a, so that the first external electrode 52a is formed to have a substantial T-shaped section.

As understood from FIG. 33, various elements on the opposite side of the tip 5 (i.e. the second pole 5b1, the second external electrode 52b, the second resin substrate 56b and the through-hole 56b) are similar to the above-mentioned elements, respectively.

The manufacturing method of the semiconductor device 51 of the fifth embodiment will be described with reference to FIGS. 34 and 35.

First, a plurality of resin substrates 56 (56a, 56b) are prepared. Preferably, FR-4 or BT resin is available for the material forming the resin substrates 56.

For instance, by means of laser, drill or the like, a plurality of through-holes 56ba, 56aa are formed in the substrates 56b, 56a respectively, at regular intervals. The intervals between the adjoining through-holes 56ba, 56aa are optionally determined in light of the width of a dicing blade used in the later-mentioned dicing process, the position of the semiconductor chip 5 and so on. Also, the diameters of the through-holes 56ba, 56aa are determined corresponding to the required performance of the semiconductor device 51 on the assumption of certain connection with the poles 5b1, 5a1 on the surfaces 5b, 5a of the semiconductor chip 5.

Next, a plurality of through-holes 53a are formed in a sheet-shaped sealing material 53′ at the same pitch as the interval of the through-holes 56ba of the second resin substrate 56b by means of laser, drill or the like. Each of the through-holes 53a is provided for accommodating the semiconductor chip 5 while making its surfaces except for the first and the second surfaces 5a, 5b contact with respective surfaces defining the through-hole 53a. Next, using a laminator device, the so-formed sealing material 53′ is temporarily fixed on the second resin substrate 56b under slight pressure with heat. In fixing, the positioning of the second resin substrate 56b with respect to the sealing material 53′ is accomplished by according a diametral center of each through-hole 56b with a diametral center of the through-hole 53a.

Thereupon, the semiconductor chips 5 are fitted in the through-holes 53a in the sealing material 53′ and successively, the first resin substrate 56a is mounted on the semiconductor chips 5 and the sealing material 53′. In mounting, the first resin substrate 56a is positioned so that the through-holes 56a oppose the through-holes 56ba in the second resin substrate 56b through the semiconductor chips 5, respectively. FIG. 32 shows the so-positioned first resin substrate 56a on the semiconductor chips 5 and the sealing material 53′. In this state, pressure with heat is applied on the first resin substrate 56a and the second resin substrate 56b toward the semiconductor chips 5 and the sealing material 53′. By this heating and pressing process, the sheet-shaped sealing materials 53′ are molten at e.g. 130 degrees centigrade and subsequently hardened at approx. 175 degrees centigrade, so that these elements (i.e. the first resin substrate 56a, the semiconductor chips 5, the sealing material 53′ and the second resin substrate 56b) are integrated into one body.

At this moment, the first and the second poles 5a1, 5b1 on the first and the second surface 5a, 5b of each semiconductor chip 5 are not obstructed by the first and the second resin substrates 56a, 56b due to the through-holes 56aa, 56ba, respectively.

Next, the plating process is carried out. The plating is applied on all of the through-holes 56aa, 56ba, one surface of the first resin substrate 56a opposed to the other surface in contact with the semiconductor chips 5 and the sealing material 53′ and one surface of the second resin substrate 56b opposed to the other surface in contact with the semiconductor chips 5 and the sealing material 53′, forming the external electrodes 52. Depending on the plating process, the electrodes 52 are made of copper (Cu), nickel (Ni), tin (Sn) or the like. Alternatively, the electrodes 52 may be formed by use of solder paste.

After completing the plating process, the resultant integrated body (assembly) is diced along broken lines of FIG. 35 into the semiconductor devices 51. Thus, the semiconductor devices 1 are dipped into plating liquid, so that plating films 54 are formed on the first external electrodes 52a and the second external electrodes 52b. In this way, the semiconductor device 51 of FIGS. 32 and 33 is completed.

Therefore, also in the sixth embodiment, it is possible to provide a semiconductor device and its manufacturing method both capable of ensuring high reliability while improving its electrical characteristics with the structure requiring no bonding wires and also improving the productivity with raised process yield.

Particularly, by plating the external electrodes, it is possible to produce the metal-to-metal joint in the connection between the poles of the semiconductor chip and the external electrodes. Thus, it is possible to prevent the semiconductor chip from being broken, for example, its breakage originating in one boundary between the semiconductor chip and the conductive member and another boundary between the conductive member and the external electrode at the package reliability evaluation test (e.g. share test) or at a substrate's bending due to heat of use.

The color of the sealing material 53 may be selected optionally. Therefore, by adopting the sealing materials 53′ in different colors in sealing up the semiconductor chips, it is also possible to produce the semiconductor devices 51 representing their polarity individually. Needless to say, by adjusting the thicknesses of the resin substrates and the sealing material or the intervals or sizes of the through-holes, it is possible to modify the dimensions of the semiconductor device with ease.

### 7^{th}. Embodiment

The seventh embodiment of the present invention will be described below. Also in the seventh embodiment, elements identical to those of the first to the fifth embodiments are indicated with the same reference numerals and their overlapping descriptions are eliminated.

The difference between the seventh embodiment and the sixth embodiment resides in the profiles of the external electrodes.

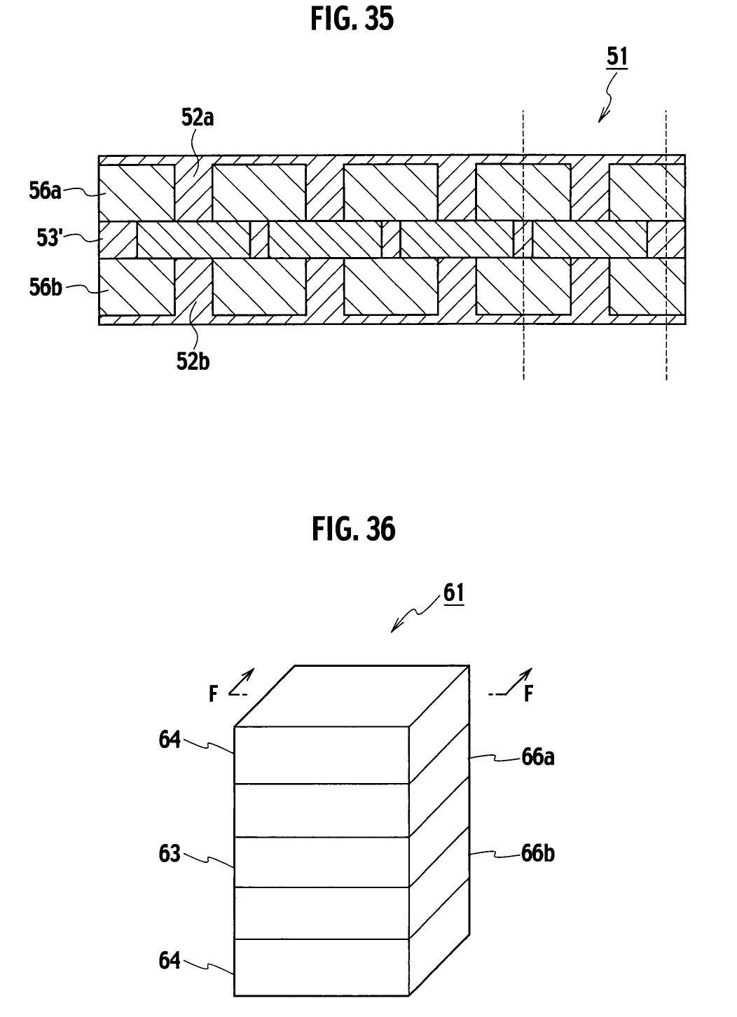

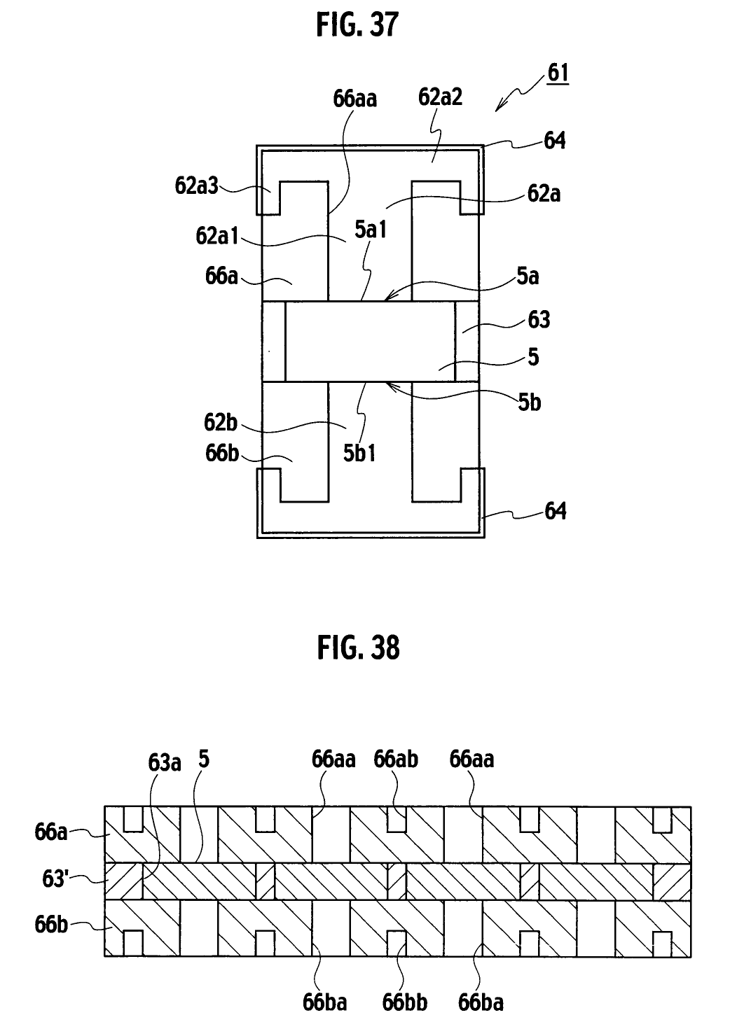

According to the seventh embodiment, a semiconductor device 61 is provided in the form of a substantially-rectangular parallelepiped, as shown in FIG. 36. The semiconductor tip 5 (not shown) is sealed up with a sealing member 63. The sealing member 63 is interposed between a first resin substrate 66a and a second resin substrate 66b both of which will be generically referred to as “resin substrates 66” after. On both sides of the device 61 in the longitudinal direction, a first external electrode 62a and a second external electrode 62b (see FIG. 37) which will be generically referred to as “external electrodes 62” after, are arranged and also coated with a pair of plating films 64 respectively, thereby forming a pair of electrodes each having five surfaces.

In the semiconductor device 61 of the seventh embodiment, the plating film 61 has a thickness (length in the longitudinal direction of the device 61) larger than that of the plating film 54 of the previous device 51. This difference in thickness is derived from a difference in profile of the external electrodes 62 (62a, 62b).

As shown in FIG. 36, basically, the constitution of the semiconductor device 61 is similar to that of the semiconductor device 51 of the sixth embodiment. We now describe a difference between the external electrodes 62 and the external electrodes 52, taking the first external electrode 62a as an example.

The first external electrode 62a is formed by a first conductive path 62a1, a second conductive path 62a1 and a pair of third conductive paths 62a3, providing a substantial-T shaped section. These conductive paths are integrated to one body since the external electrode 62 is formed by the plating.

The first conductive path 62a1 corresponding to a center shaft of the T-shaped section has one end connected to the first pole 5a1 on the first surface 5a of the chip 5. The first conductive path 62a1 is provided by applying plating on a through-hole 66aa formed in the first resin substrate 66a. The above-mentioned metal-to-metal joint is realized between the first external electrode 62a and the first pole 5a1 through this plating.

The other end of the first conductive path 62a1 is joined to the second conductive path 62a2. The second conductive path 62a2 has a sectional area larger than that of one end the first conductive path 62a1 connected to the first pole 5a1.

The second conductive path 62a2 is connected, on both sides in the shortitudinal direction of the device 61, with the third conductive paths 62a3 shorter than a longitudinal length of the first conductive path 62a1 (or a depth of the through-hole 66aa). The electrode having five surfaces is provided by forming the plating film 64 on the second conductive path 62a2 and the third conductive paths 62a3.

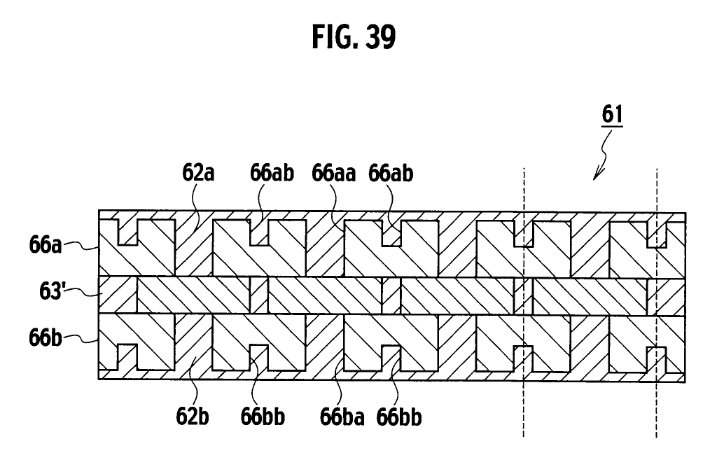

The manufacturing method of the semiconductor device 61 of the sixth embodiment will be described with reference to FIGS. 38 and 39.

First, a plurality of resin substrates 66 (66a, 66b) are prepared. Preferably, FR-4 or BT resin is available for the material forming the resin substrates 66.

For instance, by means of laser, drill or the like, a plurality of through-holes 66ba, 66aa are formed in the substrates 66b, 66a respectively, at regular intervals. The intervals between the adjoining through-holes 66ba, 66aa are optionally determined in light of the width of a dicing blade used in the later-mentioned dicing process, the position of the semiconductor chip 5 and so on. Also, the diameters of the through-holes 66ba, 66aa are determined corresponding to the required performance of the semiconductor device 61 on the assumption of certain connection with the poles 5b1, 5a1 on the surfaces 5b, 5a of the semiconductor chip 5.

Next, a plurality of through-holes 63a are formed in the sheet-shaped sealing material 63′ at the same pitch as the interval of the through-holes 66ba of the second resin substrate 66b by means of laser, drill or the like. Each of the through-holes 63a is provided for accommodating the semiconductor chip 5 while making its surfaces except for the first and the second surfaces 5a, 5b contact with respective surfaces defining the through-hole 63a. Next, using a laminator device, the so-formed sealing material 63′ is temporarily fixed on the second resin substrate 66b under slight pressure with heat. In fixing, the positioning of the second resin substrate 66b with respect to the sealing material 63′ is accomplished by according a diametral center of each through-hole 66b with a diametral center of the through-hole 63a.

Thereupon, the semiconductor chips 5 are fitted in the through-holes 63a in the sealing material 63′ and successively, the first resin substrate 66a is mounted on the semiconductor chips 5 and the sealing material 63′. In mounting, the first resin substrate 66a is positioned so that the through-holes 66a oppose the through-holes 66ba in the second resin substrate 66b through the semiconductor chips 5, respectively. FIG. 35 shows the so-positioned first resin substrate 66a on the semiconductor chips 5 and the sealing material 63′. In this state, pressure with heat is applied on the first resin substrate 66a and the second resin substrate 66b toward the semiconductor chips 5 and the sealing material 63. By this heating and pressing process, the sheet-shaped sealing materials 63′ are molten at e.g. 130 degrees centigrade and subsequently hardened at approx. 175 degrees centigrade, so that these elements (i.e. the first resin substrate 66a, the semiconductor chips 5, the sealing material 63′ and the second resin substrate 66b) are integrated into one body.

At this moment, the first and the second poles 5a1, 5b1 on the first and the second surface 5a, 5b of each semiconductor chip 5 are not obstructed by the first and the second resin substrates 66a, 66b due to the through-holes 66aa, 66ba, respectively.

Citing an example of the first resin substrate 66a, as shown in FIG. 38, a plurality of grooves 66ab are formed in the first resin substrate 66a by means of dicing. Each of the grooves 66ab has a depth smaller than that of the through-hole 66aa and is positioned at the midpoint of an interval between the diametral center of one through-hole 66aa and the adjoining through-hole 66aa. These grooves are also formed in the second resin substrate 66b similarly. Thus, the second resin substrate 66b is provided with a plurality of grooves 66bb.

The formation of the grooves 66ab, 66bb is directed to easy fabrication of the electrodes each having five surfaces. That is, by forming the grooves 66ab, 66bb in the resin substrates 66, it becomes possible to form the above-mentioned third conductive paths, broadening an area to be coated with the plating films.

Thereafter, the plating is applied on all of the through-holes 66aa, 66ba, the grooves 66ab, 66bb, one surface of the first resin substrate 66a opposed to the other surface in contact with the semiconductor chips 5 and the sealing material 63′ and one surface of the second resin substrate 66b opposed to the other surface in contact with the semiconductor chips 5 and the sealing material 63′, forming the external electrodes 62, as shown in FIG. 39. Depending on the plating process, the electrodes 62 are made of copper (Cu), nickel (Ni), tin (Sn) or the like. Alternatively, the electrodes 62 may be formed by use of solder paste.

After completing the plating process, as shown with broken lines of FIG. 39, the resultant integrated body (assembly) is diced along the centers of the grooves 66ab, 66bb into the semiconductor devices 61. In this state, the second conductive paths 62a2, 62b2 and the third conductive paths 62a3, 62b3 (as the electrodes 62) are exposed to the outside of the semiconductor device 61.

In the seventh embodiment, the plating films 64 are formed on the first external electrode 62a and the second external electrode 62b by means of barrel plating (not shown). With the adoption of barrel plating, it is possible to allow the external electrodes 62 to be coated with the plating films 64 with ease. In this way, the semiconductor device 61 of FIGS. 36 and 37 is completed.

Therefore, also in the seventh embodiment, it is possible to provide a semiconductor device and its manufacturing method both capable of ensuring high reliability while improving its electrical characteristics with the structure requiring no bonding wires and also improving the productivity with raised process yield.

Particularly, by plating the external electrodes, it is possible to produce the metal-to-metal joint in the connection between the poles of the semiconductor chip and the external electrodes. Thus, it is possible to prevent the semiconductor chip from being broken, for example, its breakage originating in one boundary between the semiconductor chip and the conductive member and another boundary between the conductive member and the external electrode at the package reliability evaluation test (e.g. share test) or at a substrate's bending due to heat of use.

Further, with the adoption of barrel plating, there is no need of dipping the semiconductor device in plating liquid, different from the sixth embodiment. Therefore, the deposition of the plating films on the external electrodes can be simplified furthermore, allowing the manufacturing process to be simplified.

The color of the sealing material 73 may be selected optionally. Therefore, by adopting the sealing materials 73 in different colors in sealing up the semiconductor chips, it is also possible to produce the semiconductor devices 71 representing their polarity individually. Needless to say, by adjusting the thicknesses of the resin substrates and the sealing material or the intervals or sizes of the through-holes, it is possible to modify the dimensions of the semiconductor device with ease.

As is clear from the above description, the present invention will become more fully apparent from the following description and appended claims taken in conjunction with the accompany drawings.

Although the present invention has been described above by reference to seven embodiments of the invention, this invention is not limited to these embodiments and modifications will occur to those skilled in the art, in light of the teachings. Further, various inventions may be made by combining a variety of constituents disclosed in the embodiments with each other appropriately. For example, some constituents may be removed from the whole constituents in the embodiments. Moreover, constituents in one embodiment may be combined with a semiconductor device of the other embodiment appropriately. The scope of the invention is defined with reference to the following claims.

This application is based upon the Japanese Patent Applications No. 2007-245852, filed on Sep. 21, 2007, the entire content of which is incorporated by reference herein.

What is claimed is:

1. A semiconductor device comprising:
a semiconductor chip having a first surface on which a first pole of a semiconductor element is arranged and a second surface on which a second pole of the semiconductor element is arranged, the first surface opposing the second surface;
a first conductive member connected to the first surface of the semiconductor chip;
a second conductive member connected to the second surface of the semiconductor chip;
a first external electrode connected to the first conductive member, the first external electrode having a contact area larger than that of the first conductive member;
a second external electrode connected to the second conductive member, the second external electrode having a contact area larger than that of the second conductive member; and
a sealing member arranged between the first external electrode and the second external electrode to seal up the semiconductor chip, the first conductive member and the second conductive member, wherein
the sealing member is made of a material that can be molten and subsequently hardened by heating.

2. The semiconductor device of claim 1, wherein
the first external electrode and the second external electrode are coated with plating films respectively.

3. A semiconductor device comprising:
a semiconductor chip having a first surface on which a first pole of a semiconductor element is arranged and a second surface on which a second pole of the semiconductor element is arranged, the first surface opposing the second surface;
a conductive member connected to the first surface of the semiconductor chip;
an external electrode connected to the first conductive member, the first external electrode having a contact area larger than that of the first conductive member; and
a sealing member arranged around the semiconductor chip and the conductive member to seal up the semiconductor chip and the conductive member and the second conductive member, wherein
the sealing member is made of material that can be molten and subsequently hardened by heating.

4. A manufacturing method of a semiconductor device, comprising the steps of:
preparing a first sheet-shaped sealing material and a second sheet-shaped sealing material;
forming a plurality of through-holes in the first sheet-shaped sealing material and the second sheet-shaped sealing material respectively;
adhering the first and the second sheet-shaped materials having the through-holes to a first external electrode and a second external electrode respectively;
filling a conductive material in each of the through-holes formed in the first sheet-shaped sealing material and the second sheet-shaped sealing material to thereby form a first conductive member and a second conductive member;
preparing a semiconductor chip having a first surface on which a first pole of a semiconductor element is arranged and a second surface on which a second pole of the semiconductor element is arranged, the first surface opposing the second surface;
connecting the first conductive member and the second conductive member to the first pole of the semiconductor chip and the second pole of the semiconductor chip, respectively;
applying pressure and heat on the first external electrode and the second external electrode toward the semiconductor chip interposed between the first conductive member and the second conductive member to melt the first sheet-shaped sealing material and the second sheet-shaped sealing material thereby sealing up the semiconductor chip, the first conductive member and the second conductive member; and
further heating the first sheet-shaped sealing material and the second sheet-shaped sealing material to harden them.

5. A semiconductor device comprising:
a semiconductor chip having a first surface on which a first pole of a semiconductor element is arranged and a second surface on which a second pole of the semiconductor element is arranged, the first surface opposing the second surface;
a first conductive member connected to the first surface of the semiconductor chip;
a second conductive member connected to the second surface of the semiconductor chip; and
a sealing member arranged between the first conductive member and the second conductive member to seal up the semiconductor chip, the sealing member being made of material that can be molten and subsequently hardened by heating, wherein
each of the first conductive member and the second conductive member has one end in contact with the first and the second poles of the semiconductor chip, the one end having areas smaller than a sectional area of the semiconductor chip, and another end having an area larger than the sectional area of the semiconductor chip.

6. The semiconductor device of claim 5, wherein
each of the first conductive member and the second conductive member comprises a first conductive path for current extending from the one end to the other end, a second conductive path connected to the first conductive path perpendicularly to forming the other end of the each conductive member and at least one third conductive member connected to the second conductive path perpendicularly to extend in parallel with the first conductive path.

7. The semiconductor device of claim 6, wherein:
the sealing member is arranged so as to seal up respective intervals between the first surface of the semiconductor chip and the second conductive path of the first conductive member, between the second surface of the semiconductor chip and the second conductive path of the second conductive member and between the third conductive path of the first conductive member and the third conductive path of the second conductive member.

8. A manufacturing method of a semiconductor device, comprising the steps of:
preparing a stage and a plurality of semiconductor chips each having a first surface on which a first pole of a semiconductor element is arranged and a second surface on which a second pole of the semiconductor element is arranged, the first surface opposing the second surface;
mounting the semiconductor chips on the stage at regular intervals so that the second poles of the semiconductor chips make contact with the stage;
forming a plurality of through-holes in a sheet-shaped sealing material;
adhering the sheet-shaped material having the through-holes to an external electrode;
filling a conductive member in each of the through-holes formed in the sheet-shaped sealing material;
reversing the external electrode and successively mounting the external electrode on the semiconductor chips so that the conductive materials make contact with the first poles of the semiconductor chips;
applying pressure and heat on the external electrode toward the semiconductor chips interposed between the stage and the external electrode to melt the sheet-shaped sealing material thereby sealing up the semiconductor chips and the conductive members;
further heating the sheet-shaped sealing material to harden it;
removing the stage from the semiconductor chips;
dicing the semiconductor chips connected with each other through the conductive members along a broken line between the adjoining semiconductor chips to thereby form an individual semiconductor device; and
plating the second pole of each of the semiconductor chips and the so-hardened sheet-shaped sealing material to thereby form plating films thereon.

9. A semiconductor device comprising:
a semiconductor chip having a first surface on which a first pole of a semiconductor element is arranged and a second surface on which a second pole of the semiconductor element is arranged, the first surface opposing the second surface;
a sealing member sealing up four constituent surfaces of the semiconductor chip except the first surface and the second surface, the sealing member forming respective identical planes with the first surface and the second surface respectively;
a first conductive member connected to the whole first surface of the semiconductor chip and formed to extend from one end of the first surface to a terminal end of the sealing member through the other end of the first surface, the terminal end of the sealing member defining the identical plane with the first surface;
a second conductive member connected to the whole second surface of the semiconductor chip and formed to extend from one end of the second surface to another terminal end of the sealing member through the other end of the second surface, the other terminal end of the sealing member defining the identical plane with the second surface;
a first sealing member sealing up a part of the surface of the sealing member defining the identical plane with the first conductive member and the first surface of the semiconductor chip, the part being not covered with the first conductive member;
a second sealing member sealing up a part of the surface of the sealing member defining the identical plane with the second conductive member and the second surface of the semiconductor chip, the part being not covered with the second conductive member;
a first plating film formed on respective surface parts of the first sealing member, the first conductive member, the sealing member covered by the first conductive member and the second sealing member, the respective surface parts defining one identical plane, and also formed on surfaces perpendicular to the respective surface parts; and
a second plating film formed on respective surface parts of the second sealing member, the second conductive member, the sealing member covered by the second conductive member and the second sealing member, the respective surface parts defining another identical plane, and also formed on surfaces perpendicular to the respective surface parts.

10. A semiconductor device comprising:
a semiconductor chip having a first surface on which a first pole of a semiconductor element is arranged and a second surface on which a second pole of the semiconductor element is arranged, the first surface opposing the second surface;
a sealing member sealing up four constituent surfaces of the semiconductor chip except the first surface and the second surface, the sealing member forming respective identical planes with the first surface and the second surface respectively;
a first metal foil connected to the whole first surface of the semiconductor chip and formed to extend from one end of the first surface to a terminal end of the sealing member through the other end of the first surface, the terminal end of the sealing member defining the identical plane with the first surface;
a second metal foil member connected to the whole second surface of the semiconductor chip and formed to extend from one end of the second surface to another terminal end of the sealing member through the other end of the second surface, the other terminal end of the sealing member defining the identical plane with the second surface;
a first sealing member sealing up a part of the surface of the sealing member defining the identical plane with the first metal foil and the first surface of the semiconductor chip, the part being not covered with the first metal foil;
a second sealing member sealing up a part of the surface of the sealing member defining the identical plane with the second metal foil and the second surface of the semiconductor chip, the part being not covered with the second metal foil;
a first plating film formed on respective surface parts of the first sealing member, the first metal foil, the sealing member covered by the first metal foil and the second sealing member, the respective surface parts defining one identical plane, and also formed on surfaces perpendicular to the respective surface parts; and
a second plating film formed on respective surface parts of the second sealing member, the second metal foil, the sealing member covered by the second metal foil and the second sealing member, the respective surface parts defining another identical plane, and also formed on surfaces perpendicular to the respective surface parts.

11. The semiconductor device of claim 9, wherein
the first surface and the second surface of the semiconductor chip are sealed up so as to be parallel with respective surfaces of both the first sealing member and the second sealing member both interposed between the first plating film and the second plating film.

12. A manufacturing method of a semiconductor device, comprising the steps of:
forming a plurality of grooves in a sheet-shaped sealing material on a dicing sheet in a lattice manner;
forming a plurality of through-holes in the sheet-shaped sealing material so that each of the through-holes is positioned at a midpoint between adjoining grooves;
filling a conductive material in the grooves and the through-holes in the sheet-shaped material and additionally applying the conductive material onto the conductive material filling the grooves and the through-holes to form a flat surface, thereby forming a first component composed of a first conductive member and a first sheet-shaped sealing material and a second component composed of a second conductive member and a second sheet-shaped sealing material;
removing the dicing sheet from the second component and arranging the second component so that its contact surface in previous contact with the dicing sheet and the sheet-shaped sealing material turns up;
preparing a plurality of semiconductor chips each having a first surface on which a first pole of a semiconductor element is arranged and a second surface on which a second pole of the semiconductor element is arranged, the first surface opposing the second surface;
connecting the conductive material, which has been filled in the through-holes of the second component and also exposed to the contact surface, to the second poles of the semiconductor chips;
connecting the conductive material, which has been filled in the through-holes of the first component and also exposed to the contact surface, to the first poles of the semiconductor chips;
applying pressure and heat on the first component and the second component toward the semiconductor chips interposed between the first component and the second component to melt the first sheet-shaped sealing material and the second sheet-shaped sealing material thereby sealing up the semiconductor chips; and
further heating the first sheet-shaped sealing material and the second sheet-shaped sealing material to harden them.

13. A manufacturing method of a semiconductor device, comprising the steps of:
preparing a plurality of semiconductor chips each having a first surface on which a first pole of a semiconductor element is arranged and a second surface on which a second pole of the semiconductor element is arranged, the first surface opposing the second surface;
mounting the semiconductor chips on a sheet so that the second poles of the semiconductor chips make contact with the sheet;
expanding the sheet in a horizontal direction to thereby form gaps each between the adjoining semiconductor chips;
filling sealing members in the gaps each between the adjoining semiconductor chips so as to define one identical plane with the first surfaces of the semiconductor chips;
forming a first conductive member and a second conductive member on a first sheet-shaped sealing material and a second sheet-shaped sealing material, respectively;
connecting the first conductive member on the first sheet-shaped sealing material to the first pole of the semiconductor chip while aligning a chip's end abutting on the sealing material with an end of the first conductive member;
connecting the second conductive member on the second sheet-shaped sealing material to the second pole of the semiconductor chip while aligning another chip's end opposed to the chip's end with an end of the second conductive member;
applying pressure and heat on the first sheet-shaped sealing material and the second sheet-shaped sealing material toward the semiconductor chips interposed between the first sheet-shaped sealing material and the second sheet-shaped sealing material to melt the first sheet-shaped sealing material and the second sheet-shaped sealing material thereby sealing up the semiconductor chips;
further heating the first sheet-shaped sealing material and the second sheet-shaped sealing material to harden them;
dicing the first sheet-shaped sealing material and the second sheet-shaped sealing material along broken lines each passing through the other end of the first conductive member connected to one semiconductor chip and the other end of the second conductive member connected to another semiconductor chip adjoining the one semiconductor chip; and
plating each semiconductor device's surface exposed to an outside by the dicing step and other surfaces of the each semiconductor device perpendicular to the each semiconductor device's surface to thereby form plating films thereon.

14. A manufacturing method of a semiconductor device, comprising the steps of:
arranging a plurality of first meal foils on a first sheet-shaped sealing material at regular intervals and also forming a plurality of second meal foils on a second sheet-shaped sealing material at regular intervals;
forming a plurality of through-holes in a third sheet-shaped sealing material on a dicing sheet, for accommodating a plurality of semiconductor chips each having a first surface on which a first pole of a semiconductor element is arranged and a second surface on which a second pole of the semiconductor element is arranged, the first surface opposing the second surface;
applying first conductive adhesives on the first metal foils at positions thereof for respective contact with the first poles of the semiconductor elements;
applying second conductive adhesives on the second metal foils at positions thereof for respective contact with the second poles of the semiconductor elements;
mounting the third sheet-shaped sealing material on the second metal foils so that the second conductive adhesives applied on the second metal foils are at respective centers of the through-holes formed in the third sheet-shaped sealing material in the width direction;
fitting the semiconductor chips in the through-holes to connect the second poles with the second metal foils through the second conductive adhesives;
connecting the first poles of the semiconductor chips with the first metal foils through the first conductive adhesives;
applying pressure and heat on the first sheet-shaped sealing material and the second sheet-shaped sealing material toward the semiconductor chips interposed between the first metal foils and the second metal foils to melt the first sheet-shaped sealing material and the second sheet-shaped sealing material thereby sealing up the semiconductor chips;
further heating the first sheet-shaped sealing material and the second sheet-shaped sealing material to harden them;
dicing the first sheet-shaped sealing material and the second sheet-shaped sealing material along broken lines each passing through one end of the first metal foil in contact with the first pole of one semiconductor chip, the one end of the first metal foil abutting on the third sheet-shaped sealing material, and one end of the second metal foil in contact with the first pole of another semiconductor chip adjoining the one semiconductor chip, the one end of the second metal foil abutting on the third sheet-shaped sealing material;
plating each semiconductor device's surface exposed to an outside by the dicing step and other surfaces of the each semiconductor device perpendicular to the each semiconductor device's surface to thereby form plating films thereon.

15. A semiconductor device comprising:
a semiconductor chip having a first surface on which a first pole of a semiconductor element is arranged and a second surface on which a second pole of the semiconductor element is arranged, the first surface opposing the second surface;
a sealing member sealing up four constituent surfaces of the semiconductor chip except the first surface and the second surface, the sealing member forming respective identical planes with the first surface and the second surface respectively;
a first resin substrate abutting on the sealing member and having a through-hole formed at a position corresponding to an area of the semiconductor chip having the first pole;
a second resin substrate abutting on the sealing member and having a through-hole formed at a position corresponding to an area of the semiconductor chip having the second pole;
a first external electrode filling the through-hole of the first resin substrate and having one end connected to the first pole and another end having a section larger than an area of the first surface of the semiconductor chip;
a second external electrode filling the through-hole of the second resin substrate and having one end connected to the second pole and another end having a section larger than an area of the second surface of the semiconductor chip; and
plating films covering respective surfaces forming the other end of the first external electrode and respective surfaces forming the other end of the second external electrode.

16. The semiconductor device of claim 15, wherein
the sealing member is made from a sheet-shaped sealing material.

17. A manufacturing method of a semiconductor device, comprising the steps of:
preparing a pair of resin substrates defining a first resin substrate and a second resin substrate and a sheet-shaped sealing material;
forming a plurality of through-holes in both the first resin substrate and the second resin substrate;
forming a plurality of through-holes in the sheet-shaped sealing material;
mounting the sheet-shaped sealing material on the second resin substrate so as to accord respective diametral centers of the through-holes of the sheet-shaped sealing material with respective diametral centers of the through-holes of the second resin substrate, respectively;
fitting the semiconductor chips in the through-holes of the sheet-shaped sealing material so that respective surfaces of each of the semiconductor chips except the first surface and the second surface make contact with respective inner walls of each of the through-holes;
mounting the first resin substrate on the sheet-shaped sealing material so as to accord respective diametral centers of the through-holes of the first resin substrate with respective diametral centers of the through-holes of the sheet-shaped sealing material, respectively;
applying pressure and heat on the semiconductor chips and the sheet-shaped sealing material through the first resin substrate and the second resin substrate to melt the sheet-shaped sealing material thereby sealing up four surface of each of the semiconductor chips except the first surface and the second surface with resin;
further heating the sheet-shaped sealing material to harden it thereby bonding the first resin substrate and the second resin substrate to the sheet-shaped sealing material;
plating the through-holes formed in the first resin substrate and the second resin substrate to form a first external electrode and a second external electrode;
dicing the first resin substrate and the second resin substrate along each broken line between the adjoining semiconductor chips to form an individual semiconductor device; and
dipping five surfaces forming the first external electrode of the individual semiconductor device and five surfaces forming the second external electrode in plating liquid to thereby form plating films thereon.

18. A semiconductor device comprising:
a semiconductor chip having a first surface on which a first pole of a semiconductor element is arranged and a second surface on which a second pole of the semiconductor element is arranged, the first surface opposing the second surface;
a sealing member sealing up four constituent surfaces of the semiconductor chip except the first surface and the second surface, the sealing member forming respective identical planes with the first surface and the second surface respectively;
a first resin substrate abutting on the sealing member and having a through-hole formed at a position corresponding to an area of the semiconductor chip having the first pole;
a second resin substrate abutting on the sealing member and having a through-hole formed at a position corresponding to an area of the semiconductor chip having the second pole;
a first external electrode including a first conductive path filling the through-hole of the first resin substrate and having one end connected to the first pole, a second conductive path connected to another end of the first conductive path perpendicularly and a pair of third conductive paths each connected to the second conductive path perpendicularly to extend in parallel with the first conductive path;
a second external electrode including a first conductive path filling the through-hole of the second resin substrate and having one end connected to the second pole, a second conductive path connected to another end of the first conductive path perpendicularly and a pair of third conductive paths each connected to the second conductive path perpendicularly to extend in parallel with the first conductive path; and
plating films covering five surfaces defining the second conductive path and the third conductive paths of the first external electrode and five surfaces defining the second conductive path and the third conductive paths of the second external electrode.

19. A manufacturing method of a semiconductor device, comprising the steps of:
preparing a pair of resin substrates defining a first resin substrate and a second resin substrate and a sheet-shaped sealing material;
forming a plurality of through-holes in both the first resin substrate and the second resin substrate;
forming a plurality of through-holes in the sheet-shaped sealing material;
mounting the sealing member on the second resin substrate so as to accord respective diametral centers of the through-holes of the sheet-shaped sealing material with respective diametral centers of the through-holes of the second resin substrate, respectively;
fitting the semiconductor chips in the through-holes of the sheet-shaped sealing material so that respective surfaces of each of the semiconductor chips except the first surface and the second surface make contact with respective inner walls of each of the through-holes;
mounting the first resin substrate on the sheet-shaped sealing material so as to accord respective diametral centers of the through-holes of the first resin substrate with respective diametral centers of the through-holes of the sheet-shaped sealing material, respectively;
applying pressure and heat on the semiconductor chips and the sheet-shaped sealing material through the first resin substrate and the second resin substrate to melt the sheet-shaped sealing material thereby sealing up four surface of each of the semiconductor chips except the first surface and the second surface with resin;
forming grooves in the first resin substrate and the second resin substrate, each of the grooves being at a midpoint between both diametral centers of the adjoining through-holes and having a depth smaller than a depth of each of the through-holes;
plating the through-holes and the grooves formed in the first resin substrate and the second resin substrate to form a first external electrode and a second external electrode;
dicing the first resin substrate and the second resin substrate along each broken line between the adjoining semiconductor chips to form an individual semiconductor device; and
applying barrel plating on five surfaces forming the first external electrode of the individual semiconductor device and five surfaces forming the second external electrode in plating liquid to thereby form plating films thereon.
